(19) United States
(12) Patent Application Publication
(10) Pub. No.: US 2025/0112080 A1
(43) Pub. Date: Apr. 3, 2025

(54) WAFER STRUCTURE AND METHOD FOR MANUFACTURING SEMICONDUCTOR DEVICES

(71) Applicant: ROHM CO., LTD., Kyoto-shi (JP)

(72) Inventor: Takaaki YAMANAKA, Kyoto-shi (JP)

(73) Assignee: ROHM CO., LTD., Kyoto-shi (JP)

(21) Appl. No.: 18/979,949

(22) Filed: Dec. 13, 2024

Related U.S. Application Data
(63) Continuation of application No. PCT/JP2023/020891, filed on Jun. 5, 2023.

(30) Foreign Application Priority Data
Jun. 14, 2022 (JP) 2022-095664

(51) Int. Cl. H01L 21/683; H01L 21/304; H01L 21/78

(52) U.S. Cl. CPC H01L 21/6836; H01L 21/304; H01L 21/78; H01L 2221/68327

(57) ABSTRACT

The wafer structure includes a wafer which has a first surface on one side and a second surface on the other side, a first electrode which covers the first surface, a second electrode which covers an inward portion of the second surface such as to expose a peripheral edge portion of the second surface, and a protective tape which has characteristics that an adhesion to the peripheral edge portion of the second surface is higher than an adhesion to the second electrode and which is adhered to the peripheral edge portion of the second surface and the second electrode.

### CROSS-REFERENCE TO RELATED APPLICATIONS

The present application is a bypass continuation of International Patent Application No. PCT/JP2023/020891, filed on Jun. 5, 2023, which claims priority to Japanese Patent Application No. 2022-095664 filed in the Japan Patent Office on Jun. 14, 2022, the entire disclosures of those applications are incorporated herein by reference.

### BACKGROUND

### 1. Field of the Disclosure

The present disclosure relates to a wafer structure and a manufacturing method for semiconductor devices.

### 2. Description of the Related Art

US20220020628A1 discloses a manufacturing method for a semiconductor device including a step of forming a first electrode in a first main surface of a semiconductor wafer, a step of forming a second electrode which covers an entire area of a second main surface of the semiconductor wafer, a step of adhering a first tape to an entire area of the second main surface such as to cover the entire area of the second electrode, a step of adhering a second tape to an entire end of the semiconductor wafer such as to overlap the first tape, and a step of forming a plating layer on the first electrode in a state that the first tape and the second tape are adhered.

### BRIEF DESCRIPTION OF DRAWINGS

FIG. 1 is a plan view in which a wafer structure according to a first embodiment is viewed from the side of a first main surface.

FIG. 2 is a cross-sectional view along line II-II shown in FIG. 1.

FIG. 3 is a schematic cross-sectional view of the wafer structure shown in FIG. 1.

FIG. 4 is a plan view in which the wafer structure shown in FIG. 1 is viewed from the side of a second main surface.

FIG. 5 is a plan view which shows a layout example of a second electrode shown in FIG. 3.

FIG. 6 is an enlarged cross-sectional view which shows a peripheral edge portion of the wafer structure shown in FIG. 1 together with a second electrode according to a first configuration example.

FIG. 7A is an enlarged cross-sectional view which shows the peripheral edge portion of the wafer structure shown in FIG. 1 together with a second electrode according to a second configuration example.

FIG. 7B is an enlarged cross-sectional view which shows the peripheral edge portion of the wafer structure shown in FIG. 1 together with a second electrode according to a third configuration example.

FIGS. 8A to 8G are each a cross-sectional view which shows a manufacturing method for a semiconductor device according to the wafer structure shown in FIG. 1.

FIGS. 9A to 9C are each a cross-sectional view which shows a step of forming the second electrode.

FIG. 10 is a plan view in which a wafer structure according to a second embodiment is viewed from the side of a first main surface.

FIG. 11 is a cross-sectional view along line XI-XI shown in FIG. 10.

FIG. 12 is an enlarged cross-sectional view which shows a main portion of a functional devices shown in FIG. 11.

FIG. 13 is a schematic cross-sectional view of the wafer structure shown in FIG. 10.

FIGS. 14A to 14G are each a cross-sectional view which shows a manufacturing method for a semiconductor device according to the wafer structure shown in FIG. 10.

FIG. 15 is a plan view which shows a wafer according to a modified example.

FIG. 16 is a schematic cross-sectional view which shows a step of forming a second electrode according to a first modified example.

FIG. 17 is a schematic cross-sectional view which shows a step of forming a second electrode according to a second modified example.

FIG. 18 is a schematic cross-sectional view which shows a step of forming a second electrode according to a third modified example.

### DETAILED DESCRIPTION OF THE PREFERRED EMBODIMENTS

Hereinafter, embodiments will be described in detail with reference to the accompanying drawings. The accompanying drawings are schematic views, and are not strictly shown, and do not necessarily coincide with each other in the scale and the like. Also, the same reference sign is assigned to a structure that corresponds to each structure in the accompanying drawings, and a duplicated description of this structure is omitted or simplified. A description of a structure, which has not yet been omitted or simplified, is applied to a corresponding structure, a description of which has been omitted or simplified. In the embodiments, wordings of “first,” “second,” “third,” etc., are used, and they are symbols which are given to a name of each structure for clarifying a description order and not given for the purpose of limiting the name of each structure.

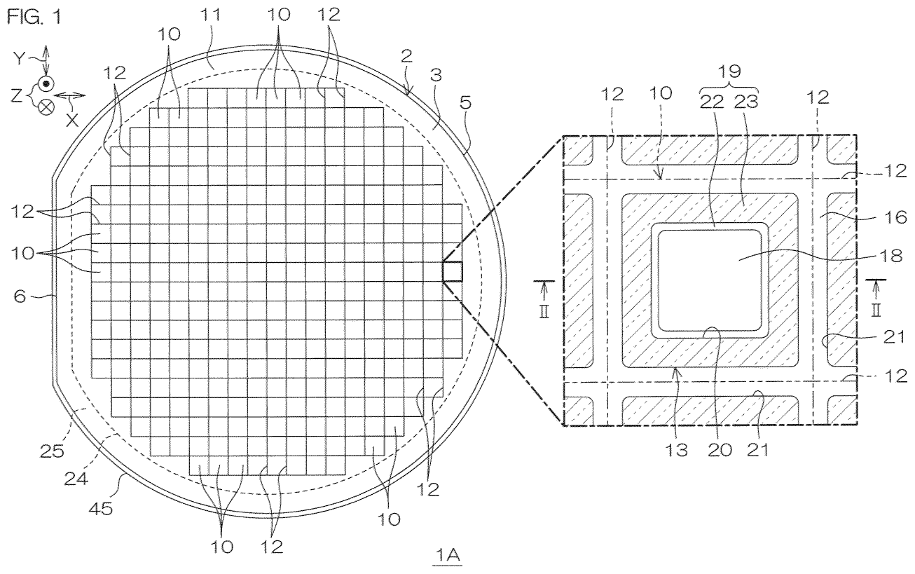

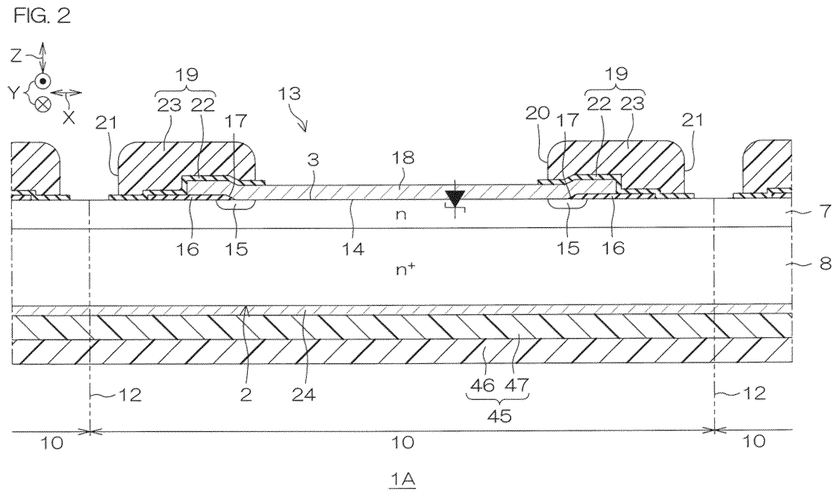

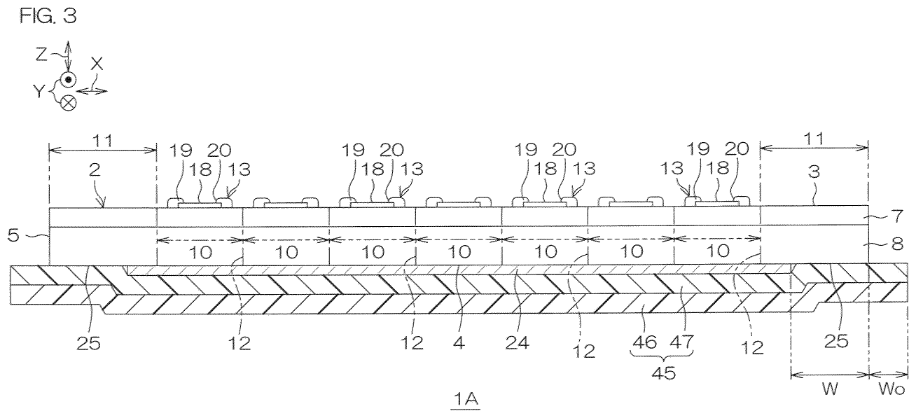

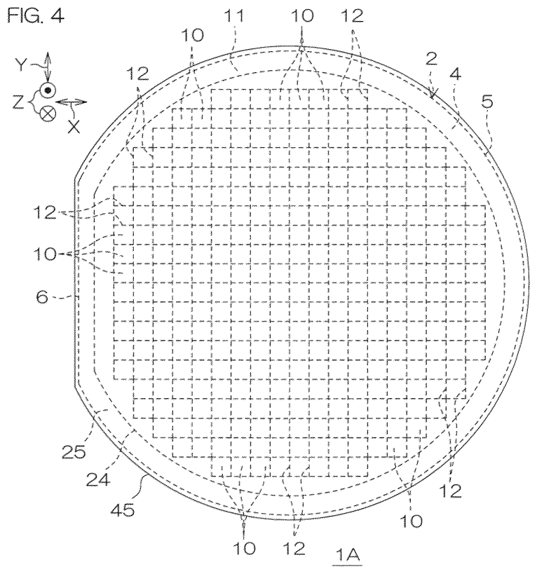

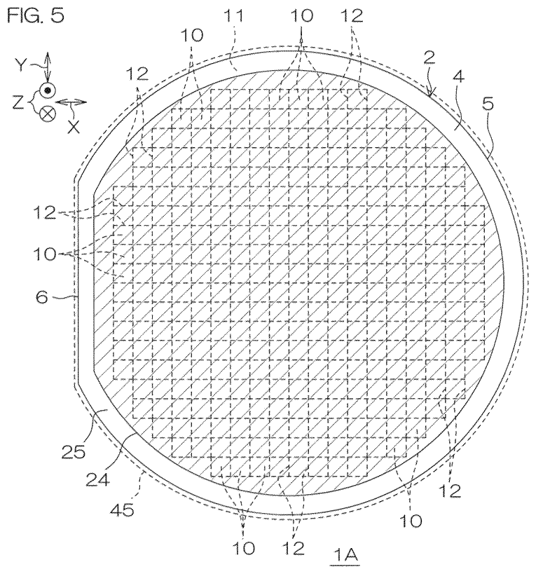

FIG. 1 is a plan view in which a wafer structure 1A according to the first embodiment is viewed from the side of a first main surface 3. FIG. 2 is a cross-sectional view along line II-II shown in FIG. 1. FIG. 3 is a schematic cross-sectional view of the wafer structure 1A shown in FIG. 1. FIG. 4 is a plan view in which the wafer structure 1A shown in FIG. 1 is viewed from the side of a second main surface 4. FIG. 5 is a plan view which shows a layout example of a second electrode 24 shown in FIG. 3.

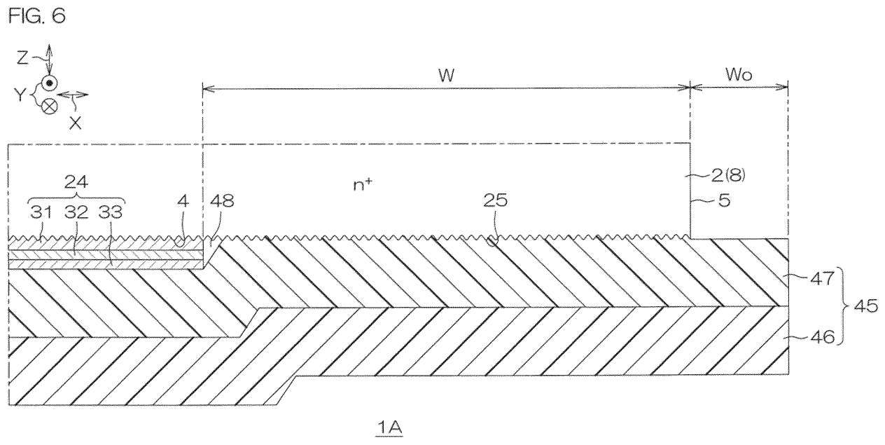

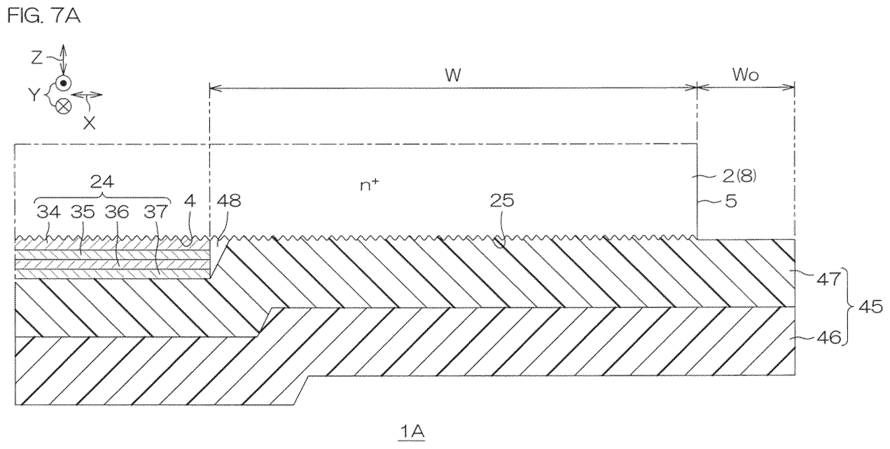

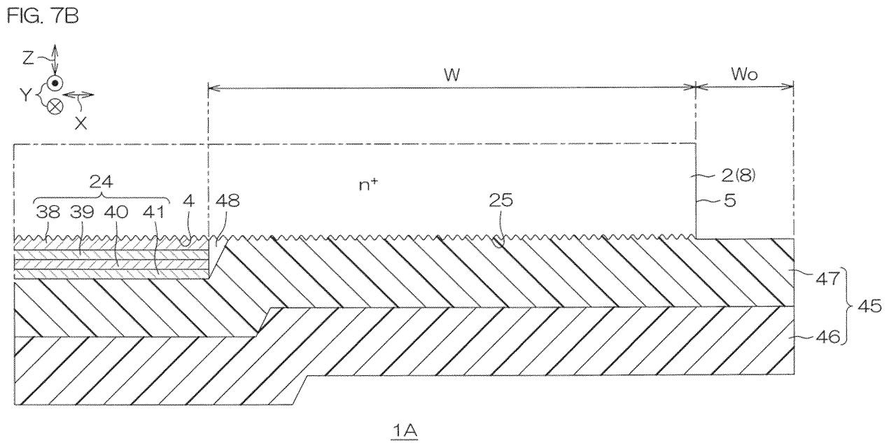

FIG. 6 is an enlarged cross-sectional view which shows a peripheral edge portion of the wafer structure 1A shown in FIG. 1 together with the second electrode 24 according to the first configuration example. FIG. 7A is an enlarged cross-sectional view which shows the peripheral edge portion of the wafer structure 1A shown in FIG. 1 together with the second electrode 24 according to the second configuration example. FIG. 7B is an enlarged cross-sectional view which shows the peripheral edge portion of the wafer structure 1A shown in FIG. 1 together with the second electrode 24 according to the third configuration example.

With reference to FIG. 1 to FIG. 6, the wafer structure 1A includes a wafer 2. In this embodiment, the wafer 2 is formed in the shape of a flat disk. As a matter of course, the wafer 2 may be formed in a flat rectangular parallelepiped shape. In this embodiment, the wafer 2 is made of a semiconductor monocrystal having a plating reaction speed which is slower than a plating reaction speed of an Si (silicon) monocrystal. That is, the wafer 2 is made of a semiconductor monocrystal which is slower in oxidation/reduction reaction speed than the Si monocrystal. It is in particular preferable that the wafer 2 is made of the semiconductor monocrystal having an Ni plating reaction speed slower than an Ni plating reaction speed of the Si monocrystal.

It is most preferable that the wafer 2 is made of a high-hard semiconductor monocrystal higher in hardness than the Si monocrystal. The wafer 2 is preferably made of a wide band gap semiconductor wafer including a wide band gap semiconductor monocrystal. That is, the wafer structure 1A is preferably a wide band gap semiconductor wafer structure. The wide band gap semiconductor is a semiconductor having a band gap higher than that of Si.

In this embodiment, the wafer 2 is made of an SiC wafer including a hexagonal SiC (silicon carbide) monocrystal as an example of a wide band gap semiconductor. That is, the wafer structure 1A is an SiC wafer structure. The hexagonal SiC monocrystal has a plurality of polytypes including 2H (hexagonal)-SiC monocrystal, 4H-SiC monocrystal, 6H-SiC monocrystal, etc. Although in this embodiment, an example in which the wafer 2 includes 4H-SiC monocrystal is shown, the wafer 2 may include an SiC monocrystal which is made of other polytypes.

The wafer 2 has a first main surface 3 on one side, a second main surface 4 on the other side and a side surface 5 which connects the first main surface 3 and the second main surface 4. Hereinafter, one direction along the first main surface 3 is referred to as a first direction X, a direction perpendicular to the first direction X along the first main surface 3 is referred to as a second direction Y, and a direction vertically intersecting the first main surface 3 is referred to as a vertical direction Z. The first direction X may be an m-axial direction of the SiC monocrystal and the second direction Y may be an a-axial direction of the SiC monocrystal. The first direction X may be an a-axial direction of the SiC monocrystal and the second direction Y may be an m-axial direction of the SiC monocrystal.

The first main surface 3 and the second main surface 4 face a c-plane of the SiC monocrystal. It is preferable that the first main surface 3 faces a silicon plane of the SiC monocrystal and the second main surface 4 faces a carbon plane of the SiC monocrystal. The first main surface 3 is a device forming surface and the second main surface 4 is a non-device forming surface. The second main surface 4 is made of a flat surface which extends horizontally from an inward portion up to a peripheral edge portion and does not have a step at the peripheral edge portion. In this embodiment, the second main surface 4 is made of a ground surface having a plurality of grinding marks which are hollowed toward the first main surface 3. A depth of the grinding mark is preferably not more than 0.5 μm. The depth of the grinding mark is in particular preferably not more than 0.1 μm.

The first main surface 3 and the second main surface 4 may have an off-angle which is inclined at a predetermined angle in a predetermined off-direction in relation to the c-plane. That is, a c-axis of the SiC monocrystal may be inclined only by the off-angle in relation to the vertical direction Z. The off-direction is preferably the a-axial direction ([11-20] direction) of the SiC monocrystal. The off-angle may be exceed 0° and be not more than 10°. The off-angle is preferably not more than 5°. The off-angle is in particular preferably not less than 2° and not more than 4.5°.

The wafer 2 has a mark 6 representing a crystal orientation of the SiC monocrystal in the side surface 5. In this embodiment, the mark 6 includes an orientation flat that has been linearly cut out in a plan view seen from the vertical direction Z (hereinafter, referred to simply as a “plan view”). In this embodiment, the orientation flat extends in the second direction Y.

The orientation flat is not necessarily required to extend in the second direction Y and may extend in the first direction X. As a matter of course, the mark 6 may include a first orientation flat extending in the first direction X and a first orientation flat extending in the second direction Y.

The wafer 2 may have a diameter of not less than 50 mm and not more than 300 mm (that is, not less than 2 inches and not more than 12 inches) in a plan view. The diameter of the wafer 2 is defined by a length of a chord passing through the center of the wafer 2 outside the mark 6.

The wafer 2 is preferably made of a thin wafer having a thickness of not less than 30 μm and less than 200 μm. The thickness of the wafer 2 may be not less than 30 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, or not less than 175 μm and not more than 200 μm. The thickness of the wafer 2 is preferably not more than 160 μm.

In this embodiment, the wafer structure 1A includes an n-type first region 7 (first semiconductor region) which is formed in a region (surface layer portion) on the first main surface 3 side inside the wafer 2. The first region 7 is formed in a layer shape extending along the first main surface 3 and exposed from the first main surface 3 and the side surface 5. In this embodiment, the first region 7 is made of an epitaxial layer (SiC epitaxial layer). The first region 7 may have a thickness of not less than 1 μm and not more than 50 μm. The thickness of the first region 7 is preferably not less than 5 μm and not more than 30 μm. The thickness of the first region 7 is in particular preferably not more than 25 μm.

In this embodiment, the wafer structure 1A includes an n-type second region 8 (second semiconductor region) which is formed in a region (surface layer portion) on the second main surface 4 side inside the wafer 2. The second region 8 has an n-type impurity concentration higher than the first region 7 and is electrically connected to the first region 7 inside the wafer 2. The second region 8 is formed in a layer shape extending along the second main surface 4 and exposed from the second main surface 4 and the side surface 5. In this embodiment, the second region 8 is made of a semiconductor substrate (SiC substrate). That is, the wafer 2 has a laminated structure which includes the substrate and the epitaxial layer.

The second region 8 may have a thickness of not less than 1 μm and less than 200 μm. The thickness of the second region 8 is preferably less than 160 μm. The thickness of the second region 8 is preferably not less than 10 μm. The thickness of the second region 8 may exceed the thickness of the first region 7. The thickness of the second region 8 may be less than the thickness of the first region 7.

The wafer structure 1A includes a plurality of device regions 10 which are provided in the first main surface 3. Each of the device regions 10 is a region corresponding to a semiconductor device (wide band gap semiconductor device/SiC semiconductor device). The plurality of device regions 10 are each set in a quadrangular shape in a plan view. In this embodiment, the plurality of device regions 10 are arrayed in a matrix manner along the first direction X and the second direction Y in a plan view.

The plurality of device regions 10 are each arrayed at an interval inwardly from a peripheral edge portion of the first main surface 3 in a plan view and demarcates a space 11 in which the plurality of device regions 10 are not present in the peripheral edge portion of the first main surface 3. That is, the wafer 2 has an inward portion having the plurality of device regions 10 and a peripheral edge portion not having the device region 10. The space 11 is formed in an annular shape which surrounds the plurality of device regions 10 in a plan view. The space 11 has a portion extending in a circular-arc shape in a region outside the mark 6 in a plan view and has a portion extending linearly in a region along the mark 6.

A length of one side of each of the device regions 10 may be not less than 0.5 mm and not more than 20 mm. The length of one side of each device region 10 is preferably not less than 1 mm. The length of one side of each device region 10 is in particular preferably not less than 2 mm. In this embodiment, the length of one side of each device region 10 is set in a range of not less than 4 mm and not more than 6 mm.

The wafer structure 1A includes a plurality of scheduled-to-be-cut lines 12 which are provided in the first main surface 3. The plurality of scheduled-to-be-cut lines 12 are set in a lattice shape extending along the first direction X and the second direction Y such as to demarcate the plurality of device regions 10.

The wafer structure 1A also includes a functional device 13 which is formed in each of the device regions 10 in the first main surface 3. Each functional device 13 is formed at an interval inwardly from a peripheral edge of each of the device regions 10. Each functional device 13 may include at least one among a switching device, a rectifying device and a passive device.

The switching device may include at least one among a MISFET (Metal Insulator r Semiconductor Field Effect Transistor), a BJT (Bipolar Junction Transistor), an IGBT (Insulated Gate Bipolar Junction Transistor) and a JFET (Junction Field Effect Transistor). The rectifying device may include at least one among a pn junction diode, a pin junction diode, a Zener diode, an SBD (Schottky Barrier Diode) and an FRD (Fast Recovery Diode). The passive device may include at least one among a resistor, a capacitor and a coil.

Each of the functional devices 13 may include a circuit network (e.g., integrated circuit such as LSI) in which at least two among the switching device, the rectifying device and the passive device are combined together. In this embodiment, each of the functional devices 13 includes the SBD. Configurations of the plurality of device regions 10 (functional devices 13) are the same, and therefore, the configuration of the single device region 10 (functional device 13) will be hereinafter described.

With reference to FIG. 5, the wafer structure 1A includes an n-type diode region 14 which is formed in a surface layer portion of the first main surface 3 at the device region 10. In this embodiment, the diode region 14 is formed by using the first region 7. The diode region 14 is formed at an interval inwardly from the peripheral edge of the device region 10. The diode region 14 is formed in a polygonal shape (in this embodiment, in a quadrangular shape) in a plan view.

The wafer structure 1A includes a p-type (second conductivity type) guard region 15 which is formed in the surface layer portion of the first main surface 3 at the device region 10. The guard region 15 is formed in a surface layer portion of the first region 7 at an interval inwardly from the peripheral edge of the device region 10. The guard region 15 is formed in a polygonal annular shape (in this embodiment, in a quadrangular annular shape) which surrounds the diode region 14 in a plan view. The guard region 15 has an inner edge portion on the inward portion side of the device region 10 and an outer edge portion on the peripheral edge side of the device region 10.

The wafer structure 1A includes a main surface insulating film 16 which selectively covers the first main surface 3 in the device region 10. The main surface insulating film 16 may include at least one among a silicon oxide film, a silicon nitride film and a silicon oxynitride film. In this embodiment, the main surface insulating film 16 has a single layer structure which includes a silicon oxide film. The main surface insulating film 16 has a contact opening 17 which exposes the diode region 14 and the inner edge portion of the guard region 15.

The main surface insulating film 16 covers an inward portion of the device region 10 at an interval inwardly from the peripheral edge of the device region 10 and exposes the first main surface 3 (first region 7) from the peripheral edge portion of the device region 10. That is, the main surface insulating film 16 exposes a boundary portion (the plurality of scheduled-to-be-cut lines 12) of the plurality of device regions 10. As a matter of course, the main surface insulating film 16 may cover the boundary portion (the plurality of scheduled-to-be-cut lines 12) of the plurality of device regions 10.

The wafer structure 1A includes a first electrode 18 which covers the first main surface 3 in the device region 10. In this embodiment, the first electrode 18 is formed as an anode electrode. The first electrode 18 is arranged at an interval inwardly from the peripheral edge of the device region 10. The first electrode 18 is formed in a polygonal shape (in this embodiment, in a quadrangular shape) along the peripheral edge of the device region 10 in a plan view. The first electrode 18 enters the contact opening 17 from above the main surface insulating film 16 and is electrically connected to inner edge portions of the diode region 14 and the guard region 15. Specifically, the first electrode 18 makes a Schottky junction with the diode region 14.

The first electrode 18 may have a laminated structure including a Ti-based metal film and an Al-based metal film that are laminated in that order from the first main surface 3 side. The Ti-based metal film may include at least one of a Ti film and a Ti alloy film. The Al-based metal film is preferably thicker than the Ti-based metal film. The Al-based metal film includes at least one of an Al film and an Al alloy film. For example, the Al-based metal film may include at least one among an AlCu alloy film, an AlSi alloy film and an AlSiCu alloy film.

The wafer structure 1A includes an insulating film 19 which covers the first electrode 18 in the device region 10. The insulating film 19 covers a peripheral edge portion of the first electrode 18 at an interval inwardly from the peripheral edge of the device region 10. The insulating film 19 demarcates a pad opening 20 in an inward portion of the device region 10 and demarcates a street opening 21 at the peripheral edge portion of the device region 10. The pad opening 20 exposes an inward portion of the first electrode 18. The pad opening 20 is formed in a polygonal shape (in this embodiment, in a quadrangular shape) along a peripheral edge of the first electrode 18 in a plan view.

The street opening 21 extends along the peripheral edge of the device region 10 and exposes the first main surface 3. Specifically, the street opening 21 is demarcated in a lattice shape extending in the first direction X and the second direction Y by the plurality of insulating films 19 which are adjacent to each other in the first direction X and in the second direction Y and exposes the boundary portion (the plurality of scheduled-to-be-cut lines 12) of the plurality of device regions 10. As a matter of course, where the main surface insulating film 16 which covers the first main surface 3 is formed at the boundary portion of the plurality of device regions 10, the street opening 21 may expose the main surface insulating film 16 at the boundary portion of the plurality of device regions 10.

The insulating film 19 is preferably thicker than the first electrode 18. A thickness of the insulating film 19 is preferably less than the thickness of the wafer 2. The thickness of the insulating film 19 may be not less than 3 μm and not more than 35 μm. The thickness of the insulating film 19 is preferably not more than 25 μm.

In this embodiment, the insulating film 19 has a laminated structure including an inorganic insulating film 22 (inorganic film) and an organic insulating film 23 (organic film) which are laminated in that order from the first electrode 18 side. The inorganic insulating film 22 may include at least one among a silicon oxide film, a silicon nitride film and a silicon oxynitride film. The inorganic insulating film 22 preferably includes an insulating material different from that of the main surface insulating film 16. In this embodiment, the inorganic insulating film 22 has a single layer structure which includes a silicon nitride film. A thickness of the inorganic insulating film 22 may be not less than 0.1 μm and not more than 5 μm.

The organic insulating film 23 is thicker than the inorganic insulating film 22 and covers the inorganic insulating film 22. The organic insulating film 23 is preferably made of a photosensitive resin film. The organic insulating film 23 may include at least one among a polyimide film, a polyamide film and a polybenzoxazole film. A thickness of the organic insulating film 23 may be not less than 3 μm and not more than 30 μm. The thickness of the organic insulating film 23 is preferably not more than 20 μm.

The organic insulating film 23 may expose one of or both of an inner edge portion and an outer edge portion of the inorganic insulating film 22. In this embodiment, the organic insulating film 23 exposes both of the inner edge portion and the outer edge portion of the inorganic insulating film 22 and demarcates the pad opening 20 and the street opening 21, together with the inorganic insulating film 22. As a matter of course, the organic insulating film 23 may cover an entire area of the inorganic insulating film 22.

The wafer structure 1A includes the second electrode 24 which covers the second main surface 4. In this embodiment, the second electrode 24 is formed as a cathode electrode and electrically connected to the second region 8 which is exposed from the second main surface 4. The second electrode 24 has a plating reaction speed faster than a plating reaction speed of the wafer 2. That is, the second electrode 24 includes an electrode material faster in oxidation reduction reaction than the wafer 2.

The second electrode 24 exposes at least a part of a peripheral edge portion of the wafer 2 as a plating reaction inhibiting portion 25. In other words, the plating reaction inhibiting portion 25 is an exposed portion which is exposed from the second electrode 24 in the second main surface 4. In this embodiment, the second electrode 24 exposes an entire periphery of the peripheral edge portion of the wafer 2 as the plating reaction inhibiting portion 25.

That is, the plating reaction inhibiting portion 25 exposes the SiC monocrystal (in this embodiment, carbon plane of the SiC monocrystal) which is exposed from the peripheral edge portion of the second main surface 4. Also, the plating reaction inhibiting portion 25 exposes the grinding marks which are formed at the peripheral edge portion of the second main surface 4. A portion of the second main surface 4 which forms the plating reaction inhibiting portion 25 is formed such as to be flush with a portion of the second main surface 4 which is hidden by the second electrode 24. That is, the plating reaction inhibiting portion 25 extends in a horizontal direction and does not form a step portion which is hollowed toward the first main surface 3 in the second main surface 4.

The plating reaction inhibiting portion 25 has a portion extending in a circular-arc shape in a region outside the mark 6, and has a portion extending linearly in a region along the mark 6 in a plan view. The plating reaction inhibiting portion 25 is formed in a region outside the plurality of device regions 10 in a plan view and faces the space 11 in the thickness direction of the wafer 2. That is, the plating reaction inhibiting portion 25 is formed in an annular shape which collectively surrounds the plurality of device regions 10 in a plan view.

An exposure width W of the plating reaction inhibiting portion 25 is preferably larger than a thickness of the second electrode 24. The exposure width W is preferably larger than a thickness of the first electrode 18. The exposure width W is preferably larger than a thickness of the insulating film 19. The exposure width W is in particular preferably larger than the thickness of the wafer 2.

The exposure width W may be not less than 0.5 mm and not more than 5 mm. The exposure width W is preferably not less than 1 mm and not more than 2 mm. The exposure width W is in particular preferably less than a length of one side of the device region 10. According to this configuration, it is possible to suppress a decrease in the number of the plurality of device regions 10 (that is, the number of the semiconductor devices) due to an introduction of the plating reaction inhibiting portion 25.

The second electrode 24 may include at least one among an Al-based metal film, a Ti-based metal film, an Ni-based metal film, a Pd-based metal film, an Au-based metal film and an Ag-based metal film. The Al-based metal film may include at least one of an Al film and an Al alloy film. For example, the Al-based metal film may include at least one among an AlCu alloy film, an AlSi alloy film and an AlSiCu alloy film.

The Ti-based metal film may include at least one of a Ti film and a Ti alloy film. The Ni-based metal film may include at least one of an Ni film and an Ni alloy film. The Pd-based metal film may include at least one of a Pd film and a Pd alloy film. The Au-based metal film may include at least one of an Au film and an Au alloy film. The Ag-based metal film may include at least one of an Ag film and an Ag alloy film.

With reference to FIG. 6, in this embodiment, the second electrode 24 has a laminated structure including a Ti film 31, an Ni film 32 and an Au film 33 which are laminated in that order from the second main surface 4 side. The Ti film 31 directly covers the second main surface 4. In this embodiment, the Ti film 31 does not form a silicide (TiSi) layer at the surface layer portion of the second main surface 4. As a matter of course, the Ti film 31 may form a silicide layer at the surface layer portion of the second main surface 4. The Ti film 31 may have a thickness of not less than 500 Å and not more than 1000 Å.

The Ni film 32 is thicker than the Ti film 31 and covers the Ti film 31. A thickness of the Ni film 32 may be not less than 5000 Å and not more than 20000 Å. The Au film 33 is thinner than the Ni film 32 and covers the Ni film 32. A thickness of the Au film 33 may be not less than 500 Å and not more than 1000 Å.

With reference to FIG. 7A, the second electrode 24 may have a laminated structure including an AlSi alloy film 34, a Ti film 35, an Ni film 36 and an Au film 37 which are laminated in that order from the second main surface 4 side. The AlSi alloy film 34 directly covers the second main surface 4. In this embodiment, the AlSi alloy film 34 does not form a silicide (AlSi) layer at the surface layer portion of the second main surface 4. As a matter of course, the AlSi alloy film 34 may form a silicide layer at the surface layer portion of the second main surface 4. The AlSi alloy film 34 may have a thickness of not less than 500 Å and not more than 2000 Å.

The Ti film 35 is thinner than the AlSi alloy film 34 and covers the AlSi alloy film 34. A thickness of the Ti film 35 may be not less than 500 Å and not more than 1000 Å. The Ni film 36 is thicker than the Ti film 35 and covers the Ti film 35. The Ni film 36 may have a thickness of not less than 5000 Å and not more than 20000 Å. The Au film 37 is thinner than the Ni film 36 and covers the Ni film 36. The Au film 37 may have a thickness of not less than 500 Å and not more than 1000 Å.

With reference to FIG. 7B, the second electrode 24 may have a laminated structure including a Ti film 38, an Ni film 39, an Au film 40 and an Ag film 41 which are laminated in that order from the second main surface 4 side. The Ti film 38 directly covers the second main surface 4. In this embodiment, the Ti film 38 does not form a silicide (TiSi) layer at the surface layer portion of the second main surface 4. As a matter of course, the Ti film 38 may form a silicide layer at the surface layer portion of the second main surface 4. The Ti film 38 may have a thickness of not less than 500 Å and not more than 1000 Å.

The Ni film 39 is thicker than the Ti film 38 and covers the Ti film 38. A thickness of the Ni film 39 may be not less than 5000 Å and not more than 20000 Å. The Au film 40 is thinner than the Ni film 39 and covers the Ni film 39. A thickness of the Au film 33 may be not less than 500 Å and not more than 1000 Å. The Ag film 41 is thicker than the Au film 40 and covers the Au film 40. A thickness of the Ag film 41 may be not less than 1000 Å and not more than 3000 Å.

The wafer structure 1A includes a protective tape 45 which is adhered to the second electrode 24 of the wafer 2. The protective tape 45 may be referred to as a “protective film,” a “supporting tape,” a “supporting film,” etc. The protective tape 45 is preferably thicker than the second electrode 24. A thickness of the protective tape 45 is preferably larger than the thickness of the first electrode 18. The thickness of the protective tape 45 is preferably larger than the thickness of the insulating film 19. The thickness of the protective tape 45 is preferably less than the thickness of the wafer 2. As a matter of course, the thickness of the protective tape 45 may be not less than the thickness of the wafer 2.

The protective tape 45 includes a base film 46 and an adhesive layer 47. The base film 46 is made of an optically transparent organic film. The base film 46 preferably has a planar shape corresponding to a planar shape of the wafer 2. In this embodiment, the base film 46 is formed in a circular shape in a plan view. Where a wafer 2 having a rectangular parallelepiped shape is adopted, the base film 46 is preferably formed in a quadrangular shape in a plan view. The base film 46 is preferably thicker than the second electrode 24. A thickness of the base film 46 is preferably larger than the thickness of the first electrode 18. The thickness of the base film 46 is preferably larger than the thickness of the insulating film 19. The thickness of the base film 46 is preferably less than the thickness of the wafer 2. As a matter of course, the thickness of the base film 46 may be not less than that of the wafer 2. The thickness of the base film 46 may be not less than 10 μm and not more than 100 μm. The thickness of the base film 46 is preferably not less than 20 μm and not more than 50 μm.

The adhesive layer 47 is provided on the one surface side of the base film 46. The adhesive layer 47 is preferably provided in an entire area of the base film 46 on the one surface side. The adhesive layer 47 is preferably thicker than the second electrode 24. A thickness of the adhesive layer 47 is preferably larger than the thickness of the first electrode 18.

The thickness of the adhesive layer 47 is preferably larger than the thickness of the insulating film 19. The thickness of the adhesive layer 47 is preferably less than the thickness of the wafer 2. As a matter of course, the thickness of the adhesive layer 47 may be not less than that of the wafer 2. The thickness of the adhesive layer 47 may be not less than 10 μm and not more than 100 μm. The thickness of the adhesive layer 47 is preferably not less than 20 μm and not more than 50 μm.

The adhesive layer 47 may include a photocurable adhesive agent which is decreased in adhesive force, for example, by irradiation of ultraviolet rays. The adhesive layer 47 has such characteristics that an adhesion (adhesive strength) to the wafer 2 is higher than an adhesion (adhesive strength) to the second electrode 24. That is, the protective tape 45 has such characteristics that an adhesion to the plating reaction inhibiting portion 25 (peripheral edge portion of the second main surface 4) is higher than an adhesion to the second electrode 24.

The adhesive strength of the protective tape 45 (adhesive layer 47) to the wafer 2 is preferably larger than 14.1 N/25 mm. For example, the adhesive strength of the protective tape 45 to an SiC wafer is preferably larger than 14.4 N/25 mm. The adhesive strength of the protective tape 45 to the second electrode 24 is not less than 8 N/25 mm and less than 14 N/25 mm. The adhesive strength of the protective tape 45 to the Au film 33 is, for example, about 8.9 N/25 mm. The adhesive strength of the protective tape 45 to the Ag film 41 is, for example, about 10 N/25 mm.

The protective tape 45 is adhered to the second main surface 4 side of the wafer 2 by bonding the adhesive layer 47 to the second electrode 24 and the plating reaction inhibiting portion 25 (peripheral edge portion of second main surface 4). The protective tape 45 covers an entire area of the second electrode 24 and extends on the plating reaction inhibiting portion 25 in a film shape from the second electrode 24. In this embodiment, the protective tape 45 covers the plating reaction inhibiting portion 25 all over an entire periphery of the peripheral edge portion of the wafer 2.

That is, the protective tape 45 covers the SiC monocrystal (in this embodiment, carbon plane of the SiC monocrystal) exposed as the plating reaction inhibiting portion 25. Also, the protective tape 45 covers the grinding marks which are formed at the plating reaction inhibiting portion 25. In this case, the grinding marks are preferably filled by the adhesive layer 47.

According to this configuration, a bonding area of the protective tape 45 (adhesive layer 47) in relation to the (peripheral edge plating reaction inhibiting portion 25 portion of the second main surface 4) is increased due to the grinding mark. Therefore, the adhesion of the protective tape 45 to the plating reaction inhibiting portion 25 (peripheral edge portion of the second main surface 4) is increased. That is, the grinding mark functions also as an anchor hole for the protective tape 45.

The bonding portion of the protective tape 45 to the plating reaction inhibiting portion 25 has a portion extending in a circular-arc shape in a region outside the mark 6, and has a portion extending linearly in a region along the mark 6 in a plan view. Specifically, the bonding portion of the protective tape 45 is formed in a region outside the plurality of device regions 10 in a plan view and faces the space 11 across the wafer 2. That is, the bonding portion of the protective tape 45 is formed in an annular shape which surrounds collectively the plurality of device regions 10 in a plan view.

The protective tape 45 may form a gap 48 between the second main surface 4 and an edge portion of the second electrode 24. That is, the protective tape 45 may be adhered to the second electrode 24 and the plating reaction inhibiting portion 25 such as to expose an edge portion of the second electrode 24. The gap 48 may be formed partially at the edge portion of the second electrode 24 or in an entire periphery thereof. As a matter of course, the protective tape 45 may cover the edge portion of the second electrode 24 partially or the entire periphery thereof so that the gap 48 will not be formed at the edge portion of the second electrode 24.

An edge portion of the protective tape 45 has a portion extending in a circular-arc shape in a region outside the mark 6, and a portion extending linearly in a region along the mark 6 in a plan view. The protective tape 45 preferably projects to a region outside the second main surface 4 along a horizontal direction from a region above the second main surface 4. According to this configuration, an entire area of the second main surface 4 can be hidden by the protective tape 45. In this case, a portion of the adhesive layer 47 which covers a peripheral edge portion of the base film 46 may be exposed from the wafer 2.

The protective tape 45 preferably expose the side surface 5 of the wafer 2. It is in particular preferable that the protective tape 45 exposes an entire area of the side surface 5. That the protective tape 45 exposes an entire area of the side surface 5 means that the base film 46 is not adhered to the side surface 5 of the wafer 2 via the adhesive layer 47. Therefore, in a configuration that the adhesive layer 47 partially overlaps a lower end portion of the side surface 5, where the base film 46 does not face the side surface 5 via the adhesive layer 47, the protective tape 45 is to expose the entire area of the side surface 5.

A protrusion width Wo of the protective tape 45 may be larger than the thickness of the wafer 2. The protrusion width Wo may be larger than the thickness of the second electrode 24. The protrusion width Wo may be larger than the thickness of the first electrode 18. The protrusion width Wo may be larger than the thickness of the insulating film 19. The protrusion width Wo is preferably less than the exposure width W of the plating reaction inhibiting portion 25. The protrusion width Wo may be not less than 0.1 mm and not more than 2 mm. The protrusion width Wo is preferably not less than 0.5 mm and not more than 1 mm.

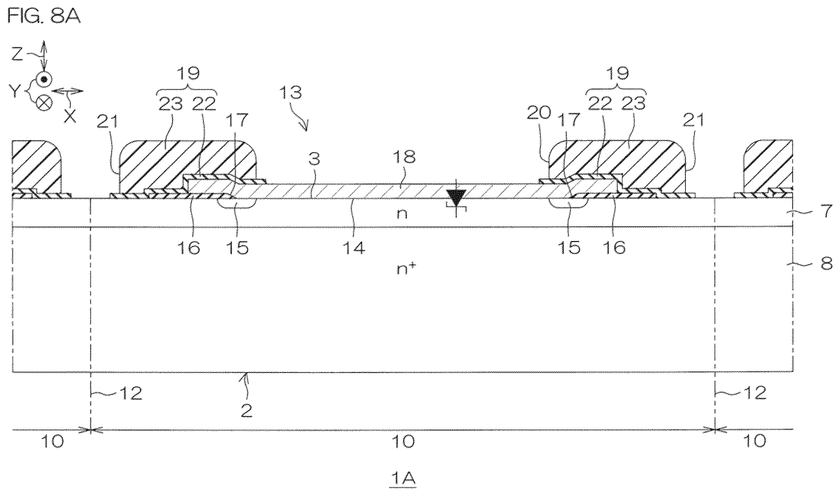

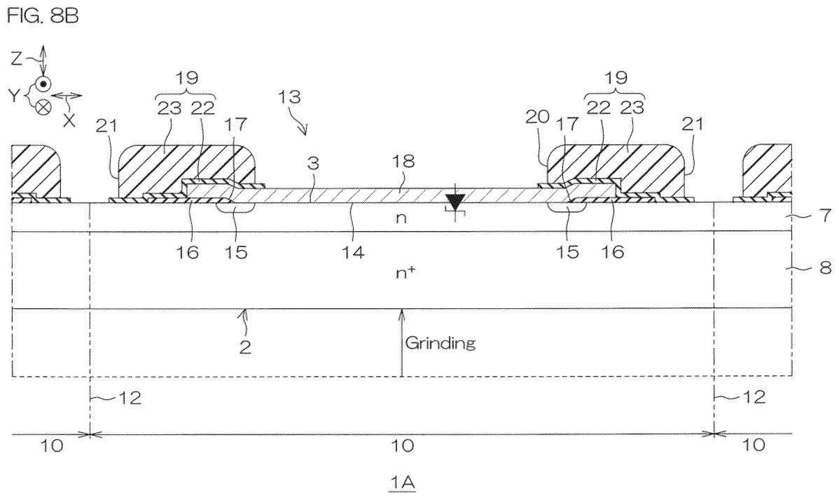

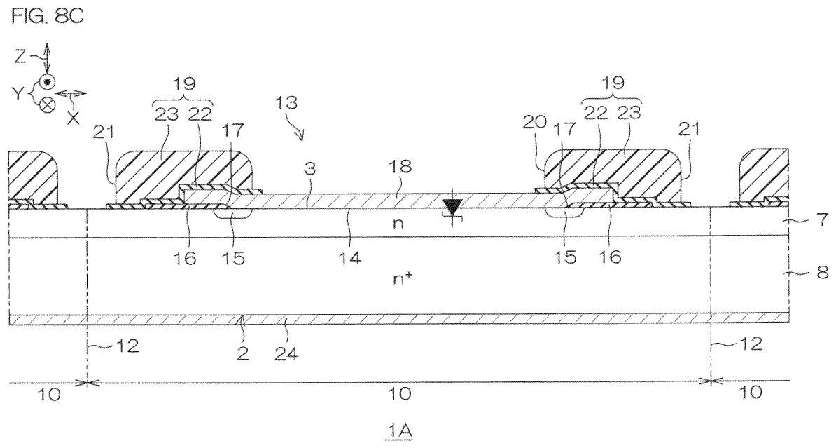

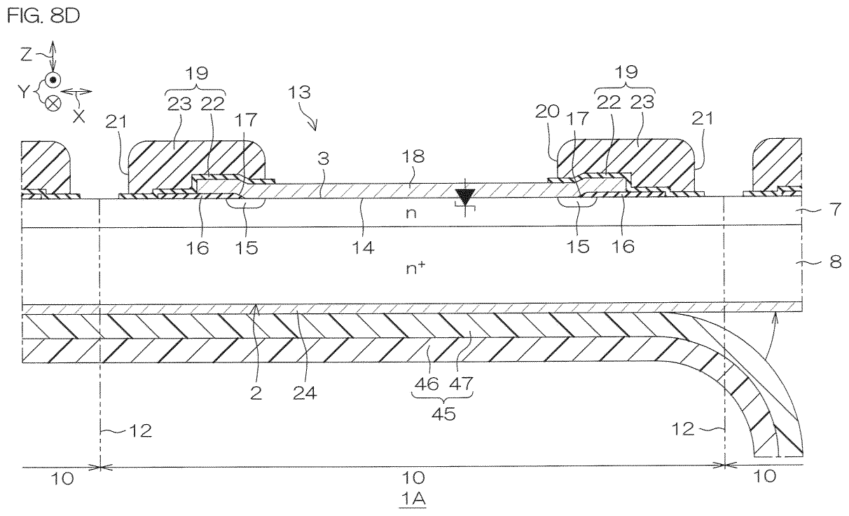

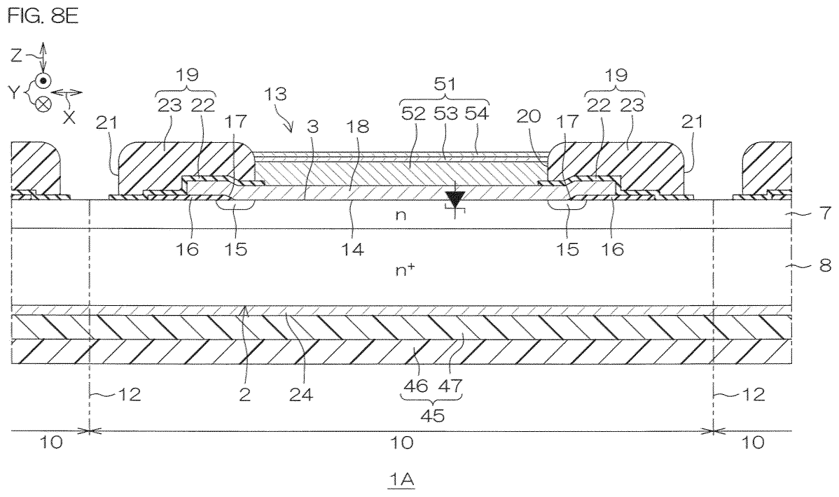

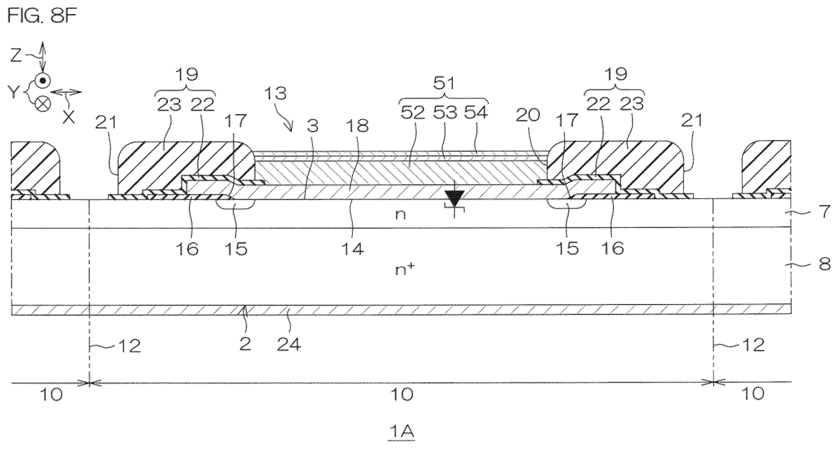

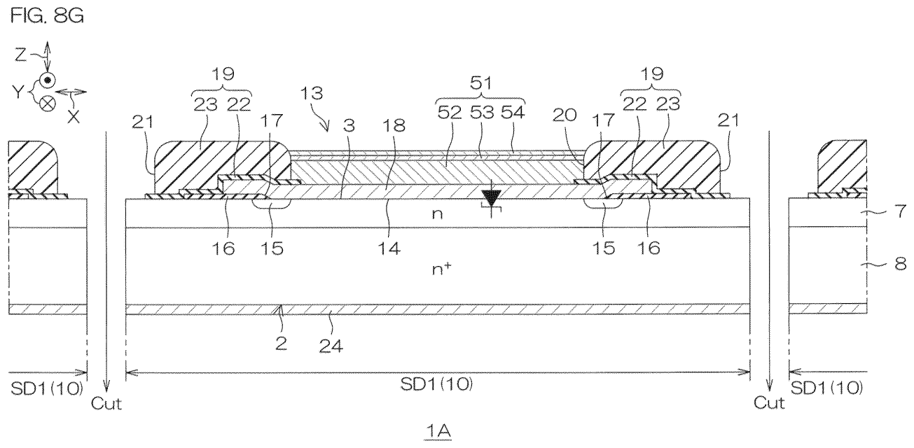

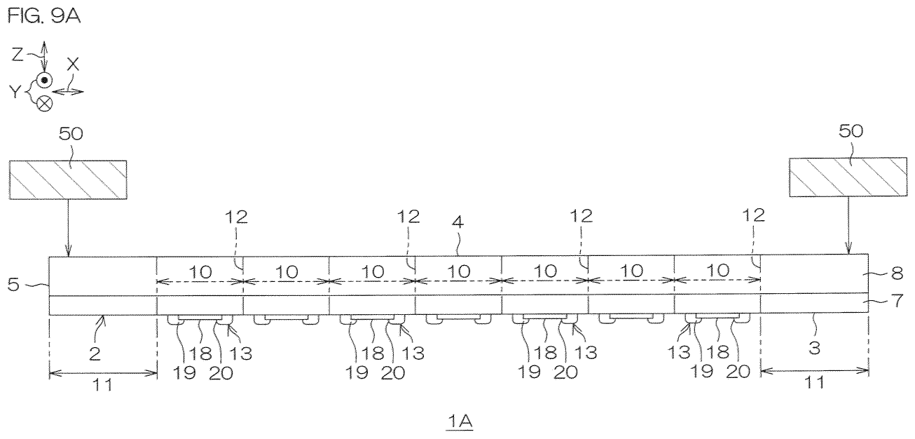

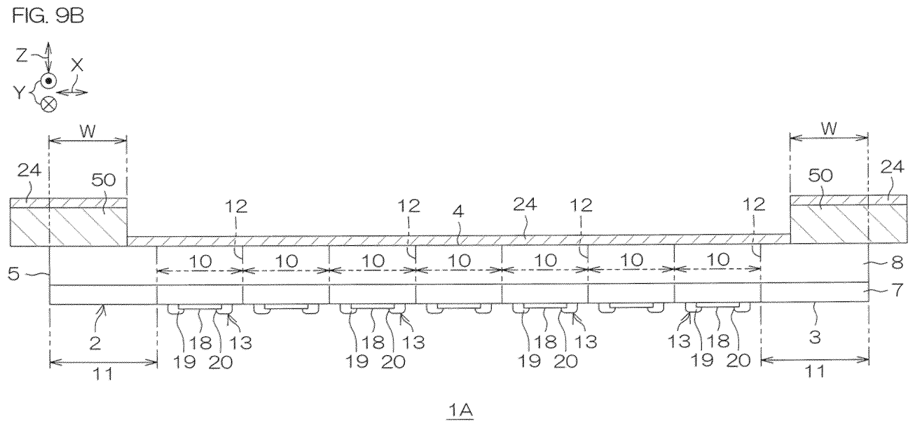

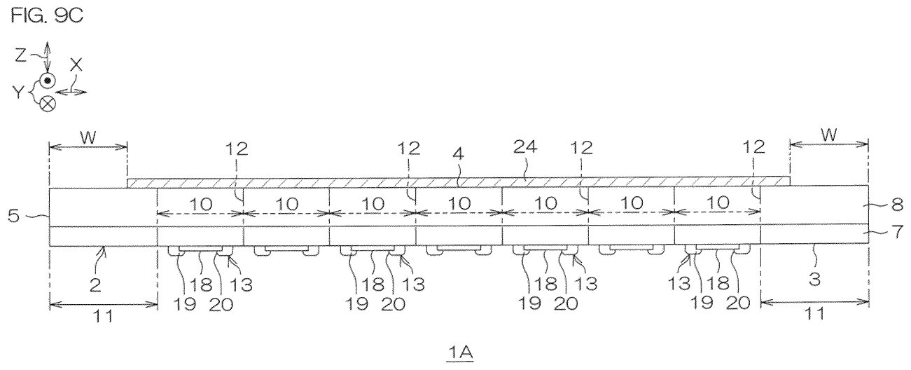

FIG. 8A to FIG. 8F are each a cross-sectional view which shows a manufacturing method for a semiconductor device SD1. FIG. 9A to FIG. 9C are each a cross-sectional view which shows a step of forming the second electrode 24. FIG. 8A to FIG. 8F (FIG. 9F to FIG. 9C) are also some of the manufacturing steps of the wafer structure 1A.

With reference to FIG. 8A, first, the wafer structure 1A before the step of forming the second electrode 24 is prepared. In each of the device regions 10, the wafer structure 1A includes the diode region 14, the guard region 15, the main surface insulating film 16, the first electrode 18 and the insulating film 19. The wafer structure 1A before the step of forming the second electrode 24 includes the wafer 2 having a thickness of not less than 200 μm. The wafer 2 may have the thickness of not less than 200 μm and not more than 1000 μm. The wafer 2 preferably has the thickness of not less than 250 μm and not more than 500 μm.

Next, with reference to FIG. 8B, a step of thinning the wafer 2 is carried out. The wafer 2 may be thinned from the second main surface 4 side by at least one of a grinding method and an etching method. In this embodiment, the wafer 2 is thinned by a grinding method for the second main surface 4. In this embodiment, the wafer 2 is ground until it reaches a thickness of less than 200 μm. Thereby, the wafer 2 is thinned, and at the same time, a grinding mark is formed in the second main surface 4.

Next, with reference to FIG. 8C, a step of forming the second electrode 24 is carried out. With reference to FIG. 9A, in this step, a masking jig 50 as a mask for the peripheral edge portion of the second main surface 4 is prepared. The masking jig 50 may be constituted of an inorganic substance such as a metal (for example, stainless steel, etc.), glass, ceramics, etc., or may be constituted of an organic substance such as a resin, etc. The masking jig 50 is configured such as to cover at least a part of the peripheral edge portion of the second main surface 4 and expose an inward portion of the second main surface 4.

That is, the masking jig 50 is configured such as to cover a region which is to be formed as the plating reaction inhibiting portion 25 in the peripheral edge portion of the second main surface 4. In this embodiment, the masking jig 50 is configured in an annular shape (specifically, in a circular annular shape) in a plan view such as to cover an entire periphery of the peripheral edge portion of the second main surface 4 and expose the inward portion of the second main surface 4.

The masking jig 50 may have a portion which extends in a circular-arc shape in a region outside the mark 6, and have a portion which extends linearly in a region along the mark 6 in a plan view. The masking jig 50 is preferably thicker than the second electrode 24 which is to be film-formed.

Next, with reference to FIG. 9B, the masking jig 50 is brought into contact with the peripheral edge portion of the second main surface 4. The masking jig 50 is brought into contact with the SiC monocrystal (in this embodiment, carbon plane of the SiC monocrystal) exposed from the peripheral edge portion of the second main surface 4. The masking jig 50 is arranged in a region outside the plurality of device regions 10 in a plan view and faces the space 11 across the wafer 2. That is, the plating reaction inhibiting portion 25 is arranged such as to collectively surround the plurality of device regions 10 in a plan view. A covering width (contact width) of the masking jig 50 in relation to the peripheral edge portion of the second main surface 4 corresponds to the exposure width W of the plating reaction inhibiting portion 25.

Next, the second electrode 24 is accumulated on the second main surface 4 and the masking jig 50 by a sputtering method, in a state that the masking jig 50 is in contact with the second main surface 4. A thickness of the second electrode 24 is less than the thickness of the masking jig 50. The second electrode 24 may include at least one among an Al-based metal film, a Ti-based metal film, an Ni-based metal film, a Pd-based metal film, an Au-based metal film and an Ag-based metal film.

The Al-based metal film, the Ti-based metal film, the Ni-based metal film, the Pd-based metal film, the Au-based metal film and the Ag-based metal film can be all film-formed by a sputtering method. The second electrodes 24 according to the first to third configuration examples (refer to FIG. 6, FIG. 7A and FIG. 7B) are formed by adjusting a film forming order of these metal films, as necessary.

Next, with reference to FIG. 9C, the masking jig 50 is removed from the second main surface 4. Thereby, a portion of the second electrode 24 which covers the masking jig 50 is removed at the same time, and the plating reaction inhibiting portion 25 having a layout corresponding to a layout of the masking jig 50 is formed at the peripheral edge portion of the second main surface 4.

Next, with reference to FIG. 8D, the protective tape 45 is adhered to the second electrode 24 and the plating reaction inhibiting portion 25 (peripheral edge portion of second main surface 4). Thereby, the wafer structure 1A shown in FIG. 1 to FIG. 6 is manufactured. The wafer structure 1A is handled in a state that the protective tape 45 is adhered.

Next, with reference to FIG. 8E, a plating film 51 is formed on the first electrode 18 by a plating method. The plating film 51 may be regarded as one component of the wafer structure 1A. In this step, an entire area of the wafer structure 1A is immersed in a plating solution and the plating film 51 is formed on the first electrode 18. This step may include a step in which the wafer structure 1A is rocked in the plating solution. The rocking step includes an agitation step in which bubbles generated by a plating reaction are dispersed in the solution. According to this step, film formation failure of the plating film 51 due to the bubbles is suppressed.

In the case of the wafer 2 having the thickness of less than 200 μm, in the rocking step, the wafer 2 is deformed by being subjected to a stress from the plating solution. The protective tape 45 protects the second electrode 24 from the plating solution, and at the same time, suppresses deformation of the wafer 2 in the plating solution. Thereby, an abnormal film formation of the plating film 51 with respect to the second electrode 24 is suppressed, and at the same time, cracks of the wafer 2 are suppressed.

Further, the second electrode 24 exposes the peripheral edge portion of the second main surface 4, and the protective tape 45 covers the peripheral edge portion of the second main surface 4. In this configuration, the protective tape 45 has characteristics that an adhesion to the peripheral edge portion of the second main surface 4 is higher than an adhesion to the second electrode 24. According to this configuration, the protective tape 45 is prevented from being peeled off from the peripheral edge portion of the second main surface 4.

Thereby, an abnormal plating film formation on the second electrode 24 due to peeling of the protective tape 45 is suppressed. Also, the protective tape 45 is improved in adhesion to the peripheral edge portion of the second main surface 4, and therefore a plating solution is prevented from entering a region between the second main surface 4 and the protective tape 45. Thereby, an abnormal plating film formation with respect to the second electrode 24 is suppressed.

Further, the peripheral edge portion of the second main surface 4 is exposed as the plating reaction inhibiting portion 25 which is slow in reaction speed with respect to a plating solution. Film formation of the plating film 51 is prevented in the plating reaction inhibiting portion 25. Therefore, even if the plating solution enters a region between the second main surface 4 and the protective tape 45, an abnormal plating film formation is suppressed by the plating reaction inhibiting portion 25.

In this embodiment, the step of forming the plating film 51 includes a step of forming an Ni plating film 52, a Pd plating film 53 and an Au plating film 54 in that order from the first electrode 18 side. The step of forming the Ni plating film 52 includes a step of forming the Ni plating film 52 on the first electrode 18 by an electroless plating method. The step of forming the Ni plating film 52 includes a step of immersing the wafer structure 1A in an Ni plating solution. Further, the step of forming the Ni plating film 52 includes a step of rocking the wafer structure 1A in the Ni plating solution.

The peripheral edge portion of the second main surface 4 is preferably exposed as the plating reaction inhibiting portion 25 slow in reaction speed with respect to at least the Ni plating solution. By suppressing an abnormal film formation of the Ni plating film 52 on the second main surface 4 side is suppressed, it is made possible to also suppress an abnormal film formation of the Pd plating film 53 and that of the Au plating film 54 on the second main surface 4 side in subsequent steps.

The Ni plating film 52 is preferably thicker than the inorganic insulating film 22. In this case, the Ni plating film 52 is preferably formed on the first electrode 18 such as to ride over an edge portion of the inorganic insulating film 22 inside the pad opening 20. The Ni plating film 52 is preferably formed at an interval to the vertical direction Z side from an opening end of the pad opening 20 toward the first electrode 18.

In this embodiment, the Ni plating film 52 covers the first electrode 18 and the inorganic insulating film 22 inside the pad opening 20 and is in contact with the organic insulating film 23. As a matter of course, the Ni plating film 52 is formed inside the pad opening 20 at an interval from the organic insulating film 23 and may cover edge portions of the first electrode 18 and the inorganic insulating film 22.

The Ni plating film 52 may have a thickness of not less than 0.1 μm and not more than 15 μm. The thickness Ni of the plating film 52 may be not less than 0.1 μm and not more than 1 μm, not less than 1 μm and not more than 3 μm, not less than 3 μm and not more than 6 μm, not less than 6 μm and not more than 9 μm, not less than 9 μm and not more than 12 μm, or not less than 12 μm and not more than 15 μm. The thickness of the Ni plating film 52 is preferably not less than 2 μm and not more than 8 μm.

The step of forming the Pd plating film 53 includes a step of forming the Pd plating film 53 on the Ni plating film 52 by an electroless plating method. The step of forming the Pd plating film 53 includes a step of immersing the wafer structure 1A in the Pd plating solution. Also, the step of forming the Pd plating film 53 includes a step of rocking the wafer structure 1A in the Pd plating solution.

The peripheral edge portion of the second main surface 4 is preferably exposed as the plating reaction inhibiting portion 25 slow in reaction speed with respect to the Pd plating solution. By suppressing an abnormal film formation of the Pd plating film 53 on the second main surface 4 side is suppressed, it is made possible to also suppress also an abnormal film formation of the Au plating film 54 on the second main surface 4 side in subsequent steps.

The Pd plating film 53 is formed in a film shape along an outer surface of the Ni plating film 52. The Pd plating film 53 is preferably formed at an interval to the Ni plating film 52 side from an opening end of the pad opening 20. The Pd plating film 53 is in contact with the organic insulating film 23 inside the pad opening 20 with respect to the vertical direction Z. As a matter of course, where the Ni plating film 52 is separated from the organic insulating film 23, the Pd plating film 53 may cover the Ni plating film 52 at an interval from the organic insulating film 23. In this case, the Pd plating film 53 may cover an edge portion of the inorganic insulating film 22.

The Pd plating film 53 preferably has a thickness which is less than the thickness of the Ni plating film 52. The thickness of the Pd plating film 53 may be not less than 0.01 μm and not more than 1 μm. The thickness of the Pd plating film 53 may be not less than 0.01 μm and not more than 0.1 μm, not less than 0.1 μm and not more than 0.2 μm, not less than 0.2 μm and not more than 0.4 μm, not less than 0.4 μm and not more than 0.6 μm, not less than 0.6 μm and not more than 0.8 μm, or not less than 0.8 μm and not more than 1 μm.

The step of forming the Au plating film 54 includes a step of forming the Au plating film 54 on the Pd plating film 53 by an electroless plating method. The step of forming the Au plating film 54 includes a step of immersing the wafer structure 1A in an Au plating solution. The step of forming the Au plating film 54 also includes a step of rocking the wafer structure 1A in the Au plating solution. The peripheral edge portion of the second main surface 4 is preferably exposed as the plating reaction inhibiting portion 25 slow in reaction speed with respect to the Au plating solution.

The Au plating film 54 is formed in a film shape along an outer surface of the Pd plating film 53. The Au plating film 54 is preferably formed at an interval to the vertical direction Z side from an opening end of the pad opening 20 toward the Pd plating film 53 side. The Au plating film 54 is in contact with the organic insulating film 23 inside the pad opening 20. As a matter of course, where the Ni plating film 52 and the Pd plating film 53 are separated from the organic insulating film 23, the Au plating film 54 may cover the Pd plating film 53 at an interval from the organic insulating film 23. In this case, the Au plating film 54 may cover an edge portion of the inorganic insulating film 22.

The Au plating film 54 preferably has a thickness less than the thickness of the Ni plating film 52. The thickness of the Au plating film 54 may be not less than 0.01 μm and not more than 1 μm. The thickness of the Au plating film 54 may be not less than 0.01 μm and not more than 0.1 μm, not less than 0.1 μm and not more than 0.2 μm, not less than 0.2 μm and not more than 0.4 μm, not less than 0.4 μm and not more than 0.6 μm, not less than 0.6 μm and not more than 0.8 μm, or not less than 0.8 μm and not more than 1 μm.

In this embodiment, an example is shown in which the plating film 51 includes the Ni plating film 52, the Pd plating film 53 and the Au plating film 54. However, the plating film 51 may have a laminated structure only including the Ni plating film 52 and the Au plating film 54 which are laminated in that order from the first electrode 18 side. As a matter of course, the plating film 51 may have a single layer structure made of the Ni plating film 52, the Pd plating film 53 or the Au plating film 54.

Next, with reference to FIG. 8F, the protective tape 45 is peeled from the second main surface 4 and the second electrode 24. This step includes a step of irradiating ultraviolet rays to the adhesive layer 47 of the protective tape 45 and decreasing an adhesive force of the adhesive layer 47. This step also includes a step of peeling the base film 46 from the second electrode 24 together with the adhesive layer 47.

Next, with reference to FIG. 8G, the wafer 2 is cut along the plurality of scheduled-to-be-cut lines 12. The wafer 2 may be cut (sliced) in the vertical direction Z by a dicing blade or may be cut (cleaved) in the vertical direction Z by a cleavage method with the use of a laser light irradiation step. In the cleavage method, inside the wafer 2, a modified layer in which a crystalline structure is partially modified by laser light irradiation is formed, and with the modified layer given as a starting point, the wafer 2 is cleaved in the vertical direction Z. Through the steps including the above, the semiconductor device SD1 (in this embodiment, SiC semiconductor device) is manufactured.

As described above, the wafer structure 1A includes the wafer 2, the first electrode 18, the second electrode 24 and the protective tape 45. The wafer 2 has the first main surface 3 on one side and the second main surface 4 on the other side. The first electrode 18 covers the first main surface 3. The second electrode 24 covers the inward portion of the second main surface 4 so that the peripheral edge portion of the second main surface 4 is exposed. The protective tape 45 is adhered to the peripheral edge portion of the second main surface 4 and the second electrode 24. The protective tape 45 has such characteristics that an adhesion to the peripheral edge portion of the second main surface 4 is higher than an adhesion of the second electrode 24.

According to this configuration, it is possible to suppress peeling of the protective tape 45 from the second main surface 4 and the second electrode 24. Thereby, where the wafer structure 1A is subjected to a manufacturing method for the semiconductor device SD1, it is possible to suppress a manufacturing failure due to peeling of the protective tape 45. Thus, it is possible to provide the wafer structure 1A contributing to the manufacture of the semiconductor device SD1 having a high reliability. For example, where the wafer structure 1A is immersed in a plating solution, it is possible to prevent the plating solution from entering a region between the second main surface 4 and the protective tape 45. Thereby, an abnormal plating film formation with respect to the second electrode 24 is suppressed.

Where the second electrode 24 has a plating reaction speed higher than a plating reaction speed of the wafer 2, the second electrode 24 preferably exposes a peripheral edge portion of the wafer 2 as the plating reaction inhibiting portion 25. That is, the peripheral edge portion of the wafer 2 is preferably made of a material which inhibits a plating film formation.

In this case, the protective tape 45 is preferably adhered to the plating reaction inhibiting portion 25. According to this configuration, it is possible to prevent a plating solution from entering a region between the plating reaction inhibiting portion 25 and the protective tape 45. Even if the plating solution enters a region between the second main surface 4 and the protective tape 45, an abnormal plating film formation can be suppressed by the plating reaction inhibiting portion 25.

The wafer 2 preferably includes the SiC monocrystal. In this case, the second electrode 24 preferably exposes the SiC monocrystal from the peripheral edge portion of the second main surface 4. The protective tape 45 is also preferably adhered to the SiC monocrystal at the peripheral edge portion of the second main surface 4. The SiC monocrystal has such physical properties that a metal is less likely to deposit by a plating method. Therefore, even if a plating solution enters a region between the second main surface 4 and the protective tape 45, it is possible to suppress an abnormal plating film formation by the SiC monocrystal.

The wafer 2 preferably has a thickness which is less than 200 μm. According to this configuration, it is possible to decrease an on-resistance due to the thickness of the wafer 2. Also, according to the protective tape 45, the wafer 2 can be handled while the relatively thin wafer 2 is prevented from deformation.

The second electrode 24 preferably exposes an entire periphery of the peripheral edge portion of the second main surface 4. In this case, the protective tape 45 is preferably adhered to the entire periphery of the peripheral edge portion of the second main surface 4. According to this configuration, peeling of the protective tape 45 from the second main surface 4 can be suppressed at the entire periphery of the peripheral edge portion of the second main surface 4. At the entire periphery of the peripheral edge portion of the second main surface 4, it is also possible to prevent a plating solution from entering a region between the second main surface 4 and the protective tape 45.

The exposure width W of the plating reaction inhibiting portion 25 (peripheral edge portion of second main surface 4) is preferably larger than the thickness of the second electrode 24. The exposure width W is preferably larger than the thickness of the wafer 2. According to these configurations, it is possible to appropriately reduce a contact risk of a plating solution with respect to the second electrode 24.

The second main surface 4 preferably has the grinding mark. In this case, the second electrode 24 preferably exposes the grinding mark at the peripheral edge portion of the second main surface 4. Also, the protective tape 45 is preferably adhered to the peripheral edge portion having the grinding mark. According to this configuration, it is possible to increase an adhesion of the protective tape 45 to the peripheral edge portion of the second main surface 4 by the grinding mark.

The second main surface 4 is preferably made of the flat surface. That is, the second main surface 4 preferably does not have a step portion hollowed toward the first main surface 3 side. According to this configuration, it is possible to appropriately suppress the formation of a fragile portion of the wafer 2 in the second main surface 4. In particular, this configuration is preferably applied to the wafer 2 of less than 200 μm.

The wafer structure 1A may include the plating film 51 which covers the first electrode 18. In this case, the second electrode 24 preferably exposes the peripheral edge portion of the wafer 2 as the plating reaction inhibiting portion 25 which inhibits the film formation of the plating film 51. The plating film 51 may include at least one among the Ni plating film 52, the Pd plating film 53 and the Au plating film 54.

The wafer structure 1A may include the plurality of device regions 10 which are set in an inward portion of the first main surface 3. In this case, the second electrode 24 preferably exposes the region outside the plurality of device regions 10, in a plan view. According to this configuration, it is possible to appropriately manufacture the semiconductor device SD1 having the second electrode 24.

In another aspect, the manufacturing method for the semiconductor device SD1 includes the step of preparing the wafer structure 1A, the step of forming the second electrode 24 and the step of adhering the protective tape 45. In the step of preparing the wafer structure 1A, the wafer structure 1A which includes the wafer 2 having the first surface on one side and the second main surface 4 on the other side as well as the first electrode 18 which covers the first surface is prepared.

In the step of forming the second electrode 24, the second electrode 24 which covers the inward portion of the second main surface 4 is formed such as to expose the peripheral edge portion of the second main surface 4. In the step of adhering the protective tape 45, the protective tape 45 which has such characteristics that an adhesion to the peripheral edge portion of the second main surface 4 is higher than an adhesion to the second electrode 24 is adhered to the peripheral edge portion of the second main surface 4 and the second electrode 24.

According to this manufacturing method, it is possible to suppress peeling of the protective tape 45 from the second main surface 4 and the second electrode 24. It is thereby possible to suppress a manufacturing failure due to the peeling of the protective tape 45. Therefore, it is possible to provide the method which contributes to the manufacture of the semiconductor device SD1 high in reliability. For example, where the wafer 2 is immersed in a plating solution in a state that the protective tape 45 is adhered, it is possible to prevent the plating solution from entering a region between the second main surface 4 and the protective tape 45. Thereby, an abnormal plating film formation with respect to the second electrode 24 is suppressed.

Where the second electrode 24 has a plating reaction speed higher than a plating reaction speed of the wafer 2, the second electrode 24 preferably exposes the peripheral edge portion of the wafer 2 as the plating reaction inhibiting portion 25. That is, the peripheral edge portion of the wafer 2 is preferably made of a material which inhibits a plating film formation.

In this case, the protective tape 45 is preferably adhered to the plating reaction inhibiting portion 25. According to the manufacturing method, it is possible to prevent a plating solution from entering a region between the plating reaction inhibiting portion 25 and the protective tape 45. Also, even if the plating solution enters a region between the second main surface 4 and the protective tape 45, it is possible to suppress an abnormal plating film formation by the plating reaction inhibiting portion 25.

It is preferable that the manufacturing method for the semiconductor device SD1 also includes a step of immersing the wafer structure 1A in a plating solution in a state that the protective tape 45 is adhered and forming the plating film 51 on the first electrode 18. According to the manufacturing method, it is possible to prevent the plating solution from entering a region between the second main surface 4 and the protective tape 45. It is thereby possible to suppress an abnormal plating film formation with respect to the second electrode 24.

The step of forming the plating film 51 preferably includes a step of rocking the wafer structure 1A in a plating solution. According to this manufacturing method, bubbles which are generated in association with plating reactions can be dispersed in the solution. Thereby, it is possible to suppress a failure in film formation of the plating film 51 due to the bubbles. Also, according to this manufacturing method, it is possible to protect the second electrode 24 from the plating solution by the protective tape 45, and at the same time, suppress the deformation of the wafer 2 in the plating solution by the protective tape 45.

Thereby, an abnormal film formation of the plating film 51 with respect to the second electrode 24 is suppressed, and at the same time, cracks of the wafer 2 are suppressed. In particular, the relatively thin wafer 2 which is less than 200 μm is likely to deform by undergoing a stress from the plating solution in the step of rocking it, however, it is possible to appropriately suppress the deformation of the relatively thin wafer 2 by the protective tape 45.

The step of forming the plating film 51 may include at least one step among the step of immersing the wafer structure 1A in the Ni plating solution and forming the Ni plating film 52, the step of immersing the wafer structure 1A in the Pd plating solution and forming the Pd plating film 53 and the step of immersing the wafer structure 1A in the Au plating solution and forming the Au plating film 54. According to this manufacturing method, it is possible to suppress, by the protective tape 45, at least one among an abnormal film formation of the Ni plating film 52, an abnormal film formation of the film Pd plating film 53 and an abnormal film formation of the Au plating film 54 on the second main surface 4 side.

The wafer 2 preferably includes the SiC monocrystal. In this case, the second electrode 24 is preferably formed such as to expose the SiC monocrystal from the peripheral edge portion of the second main surface 4. The protective tape 45 is also preferably adhered to the SiC monocrystal at the peripheral edge portion of the second main surface 4. The SiC monocrystal has such a physical property that a metal is less likely to deposit by a plating method. Therefore, even if a plating solution enters a region between the second main surface 4 and the protective tape 45, it is possible to suppress an abnormal plating film formation by the SiC monocrystal.

In the step of preparing the wafer structure 1A, it is preferable that the wafer structure 1A including the wafer 2 having a thickness of not less than 200 μm is prepared. In this case, the manufacturing method for the semiconductor device SD1 preferably includes a step of thinning the wafer 2 until the wafer 2 reaches a thickness of less than 200 μm prior to the step of forming the second electrode 24.

According to the manufacturing method, the wafer 2 can be handled while the deformation of the wafer 2 is suppressed by the wafer 2 which is relatively thick until the step of thinning the wafer 2. Then, an on-resistance due to the thickness of the wafer 2 can be decreased in the step of thinning the wafer 2. Then, after the step of adhering the protective tape 45, the wafer 2 can be handled by suppressing the deformation of the relatively thin wafer 2 by the protective tape 45.

The step of thinning the wafer 2 may include a step of grinding an entire surface of the second main surface 4 by a grinding method. In this case, the second electrode 24 is preferably formed such as to expose a grinding mark at the peripheral edge portion of the second main surface 4. The protective tape 45 is also preferably adhered to the peripheral edge portion having the grinding mark. According to the manufacturing method, it is possible to increase an adhesion of the protective tape 45 to the peripheral edge portion of the second main surface 4 by the grinding mark.

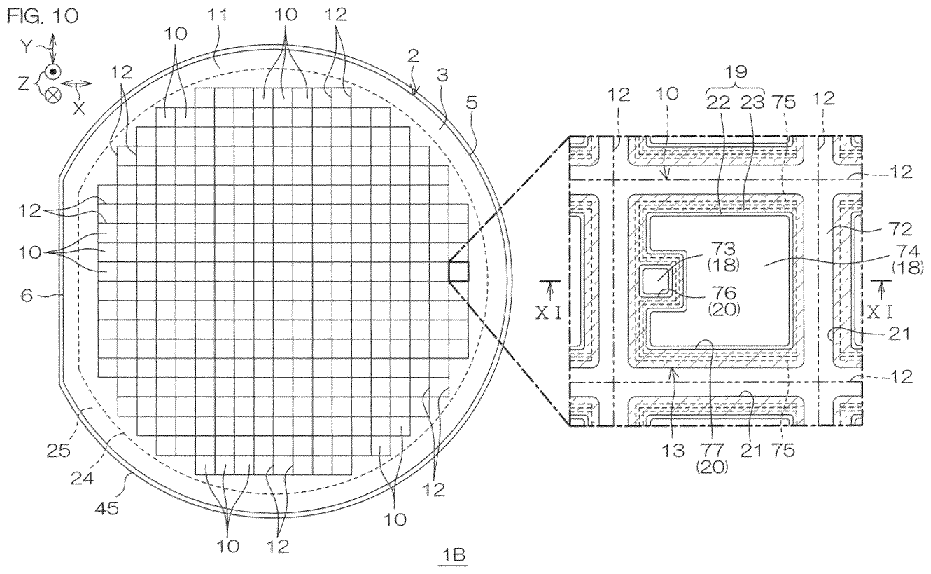

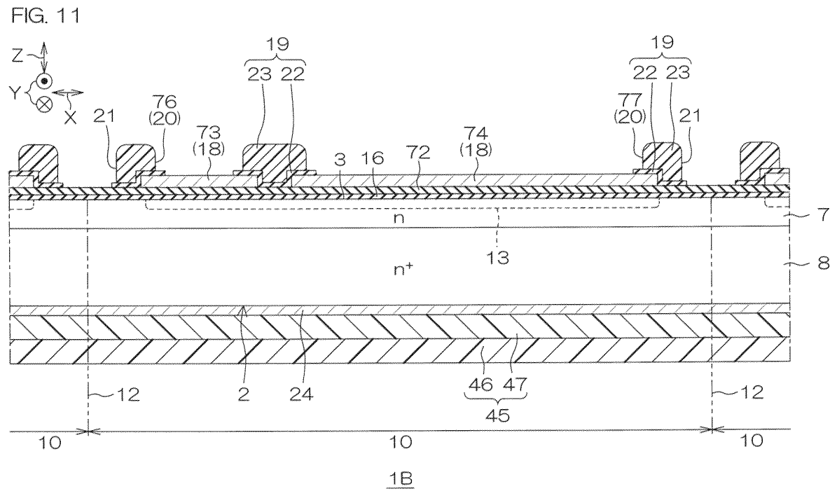

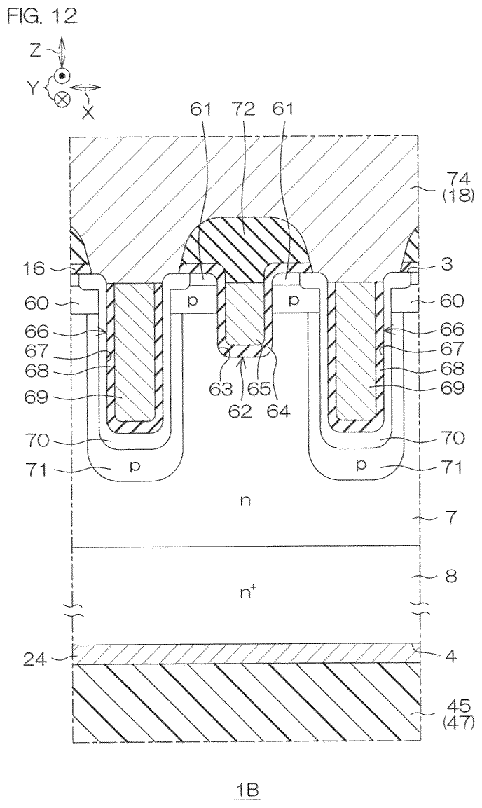

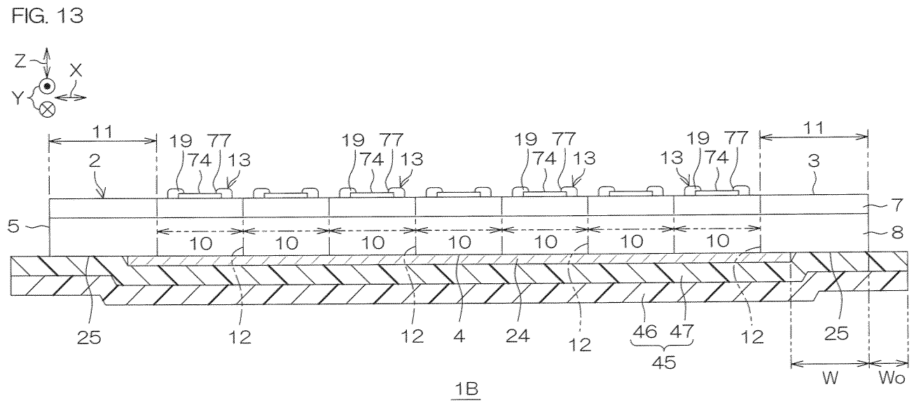

FIG. 10 is a plan view in which a wafer structure 1B according to a second embodiment is seen from the first main surface 3 side. FIG. 11 is a cross-sectional view along line XI-XI shown in FIG. 10. FIG. 12 is an enlarged cross-sectional view which shows a main portion of the functional device 13 shown in FIG. 11. FIG. 13 is a schematic cross-sectional view of the wafer structure 1B shown in FIG. 10.

With reference to FIG. 10 to FIG. 12, the wafer structure 1B has a configuration different from the aforementioned wafer structure 1A in that the functional device 13 includes a MISFET in place of the SBD. In FIG. 11, the functional device 13 is shown in a simplified manner by a broken line.

In this embodiment, the MISFET is of a trench gate type. Other configurations of the wafer structure 1B are substantially the same as those of the wafer structure 1A. Hereinafter, in the wafer structure 1B, a point different from that of the wafer structure 1A will be described. Also, hereinafter, a configuration of the single device region 10 will be described.

The wafer structure 1B includes a p-type body region 60 which is formed at the surface layer portion of the first main surface 3 in the device region 10. The body region 60 is formed at an interval to the first main surface 3 side from a bottom portion of the first region 7 and extends in a layer shape at the surface layer portion of the first main surface 3. The body region 60 may be formed in an entire area of the first main surface 3.

The wafer structure 1B includes an n-type source region 61 which is formed at the surface layer portion of the body region 60 in the device region 10. The source region 61 may be formed at an interval from the peripheral edge of the device region 10 at an inward portion of the device region 10. The source region 61 has an n-type impurity concentration higher than that of the first region 7. The source region 61 is formed at an interval to the first main surface 3 side from a bottom portion of the body region 60 and extends in a layer shape at the surface layer portion of the first main surface 3. The source region 61 forms a channel with the first region 7 inside the body region 60

The wafer structure 1B includes a plurality of first trench structures 62 which are formed at the first main surface 3 in the device region 10. The first trench structure 62 may be referred to as a “trench gate structure.” The plurality of first trench structures 62 control the inversion and the non-inversion of the channel. The plurality of first trench structures 62 penetrate through the body region 60 and the source region 61 and reach the first region 7. The plurality of first trench structures 62 may be arrayed at an interval in the first direction X in a plan view and each formed in a band shape extending in the second direction Y. The plurality of first trench structures 62 are formed at an interval to the first main surface 3 side from a bottom portion of the first region 7.

Each of the first trench structures 62 includes a first trench 63, a first insulating film 64 and a first embedded electrode 65. The first trench 63 is formed in the first main surface 3 and demarcates a wall surface of the first trench 63. The first insulating film 64 covers the wall surface of the first trench 63. The first embedded electrode 65 is embedded in the first trench 63 across the first insulating film 64. The first embedded electrode 65 faces the channel across the first insulating film 64.

The wafer structure 1B includes a plurality of second trench structures 66 which are formed at the first main surface 3 in the device region 10. The second trench structure 66 may be referred to as a “trench source structure.” The plurality of second trench structures 66 are each formed in a region between two first trench structures 62 which are adjacent to each other.

The plurality of second trench structures 66 may be each formed in a band shape extending in the second direction Y in a plan view. The plurality of second trench structures 66 penetrate through the body region 60 and the source region 61 and reach the first region 7. The plurality of second trench structures 66 are formed at an interval to the first main surface 3 side from a bottom portion of the first region 7 and formed deeper than the first trench structure 62.

Each of the second trench structures 66 includes a second trench 67, a second insulating film 68 and a second embedded electrode 69. The second trench 67 is formed in the first main surface 3 and demarcates a wall surface of the second trench 67. The second insulating film 68 covers the wall surface of the second trench 67. The second embedded electrode 69 is embedded in the second trench 67 across the second insulating film 68.

The wafer structure 1B includes a plurality of p-type contact regions 70 which are each formed in a region along the plurality of second trench structures 66 inside the wafer 2 in the device region 10. The plurality of contact regions 70 have a p-type impurity concentration higher than that of the body region 60. Each of the contact regions 70 covers a side wall and a bottom wall of each second trench structure 66 and is electrically connected to the body region 60.

The wafer structure 1B includes a plurality of p-type well regions 71 which are each formed in a region along the plurality of second trench structures 66 inside the wafer 2 in the device region 10. Each of the well regions 71 has a p-type impurity concentration higher than that of the body region 60 and lower than that of the contact region 70. Each of the well regions 71 covers a corresponding second trench structure 66 across a corresponding contact region 70. Each of the well regions 71 covers a side wall and a bottom wall of the corresponding second trench structure 66 and is electrically connected to the body region 60.

The wafer structure 1B includes the main surface insulating film 16 which covers the first main surface 3 in the device region 10. The main surface insulating film 16 continues to the first insulating film 64 and the second insulating film 68 and exposes the first embedded electrode 65 and the second embedded electrode 69. In this embodiment, the main surface insulating film 16 covers a peripheral edge portion of the device region 10 (boundary portion of the plurality of device regions 10). That is, the main surface insulating film 16 covers an entire area of the first main surface 3. As a matter of course, the main surface insulating film 16 may expose the peripheral edge portion of the device region 10 (boundary portion of the plurality of device regions 10).

The wafer structure 1B includes an interlayer insulating film 72 which covers the main surface insulating film 16 in the device region 10. The interlayer insulating film 72 may include at least one among a silicon oxide film, a silicon nitride film and a silicon oxynitride film. The interlayer insulating film 72 covers the plurality of first trench structures 62 and the plurality of second trench structures 66.

In this embodiment, the interlayer insulating film 72 covers the peripheral edge portion of the device region 10 (boundary portion of the plurality of device regions 10) across the main surface insulating film 16. The interlayer insulating film 72 may cover an entire area of the first main surface 3. As a matter of course, where the main surface insulating film 16 exposes the first main surface 3 at the peripheral edge portion of the device region 10, the interlayer insulating film 72 may expose the first main surface 3 at the peripheral edge portion of the device region 10.

As with the first embodiment, the wafer structure 1B includes a first embedded electrode 65 which is arranged on the interlayer insulating film 72 in the device region 10. The first electrode 18 may have a laminated structure including a Ti-based metal film and an Al-based metal film which are laminated in that order from the first main surface 3 side.

In this embodiment, the first electrode 18 includes a gate electrode 73 and a source electrode 74. In this embodiment, the gate electrode 73 is arranged in a region in proximity to a central portion of one side of the device region 10 in a plan view. The gate electrode 73 may be arranged at a corner portion of the device region 10 in a plan view. In this embodiment, the gate electrode 73 is formed in a quadrangular shape in a plan view.

The source electrode 74 is arranged on the interlayer insulating film 72 at an interval from the gate electrode 73. In this embodiment, the source electrode 74 is formed in a polygonal shape having a concave portion hollowed along the gate electrode 73 in a plan view. As a matter of course, the source electrode 74 may be formed in a quadrangular shape in a plan view. The source electrode 74 penetrates through the interlayer insulating film 72 and the main surface insulating film 16 and is electrically connected to the body region 60, the source region 61 and the plurality of second trench structures 66.

The wafer structure 1B includes a gate wiring electrode 75 which is led out onto the interlayer insulating film 72 from the gate electrode 73 in the device region 10. As with the gate electrode 73 (first electrode 18), the gate wiring electrode 75 may have a laminated structure including a Ti-based metal film and an Al-based metal film which are laminated in that order from the first main surface 3 side. The gate wiring electrode 75 is formed in a band shape extending along the peripheral edge of the device region 10 such as to intersect (specifically, perpendicularly intersect) end portions of the plurality of first trench structures 62 in a plan view. The gate wiring electrode 75 penetrates through the interlayer insulating film 72 and is electrically connected to the plurality of first trench structures 62.

The wafer structure 1B includes an insulating film 19 which covers the first electrode 18 in the device region 10. As with the first embodiment, the insulating film 19 has a laminated structure including the inorganic insulating film 22 and the organic insulating film 23 which are laminated in that order from the first electrode 18 side. In this embodiment, the insulating film 19 covers a peripheral edge portion of the gate electrode 73 and a peripheral edge portion of the source electrode 74 at an interval inwardly from the peripheral edge of the device region 10. The insulating film 19 covers an entire area of the gate wiring electrode 75.

The insulating film 19 demarcates the plurality of pad openings 20 which expose an inward portion of the gate electrode 73 and an inward portion of the source electrode 74 and demarcates the street opening 21 which exposes the interlayer insulating film 72 at the peripheral edge portion of the device region 10. In this embodiment, the plurality of pad openings 20 includes a gate pad opening 76 which exposes the inward portion of the gate electrode 73 and a source pad opening 77 which exposes the inward portion of the source electrode 74.

In this embodiment, the gate pad opening 76 is demarcated in a quadrangular shape along the peripheral edge of the gate electrode 73 in a plan view. In this embodiment, the source pad opening 77 is formed in a polygonal shape along the peripheral edge of the source electrode 74 in a plan view. The street opening 21 is formed in the same manner as the first embodiment.

The organic insulating film 23 may expose an edge portion of the inorganic insulating film 22 in the gate pad opening 76. The organic insulating film 23 may expose an edge portion of the inorganic insulating film 22 in the source pad opening 77. The organic insulating film 23 may expose an edge portion of the inorganic insulating film 22 in the street opening 21. As a matter of course, the organic insulating film 23 may cover an entire area of the inorganic insulating film 22.

The wafer structure 1B includes a second electrode 24 which covers the second main surface 4. In this embodiment, the second electrode 24 is formed as a drain electrode and electrically connected to the second region 8 which is exposed from the second main surface 4. The second electrode 24 is formed in the same mode as that of the first embodiment. Descriptions of the first embodiment apply to other descriptions of the second electrode 24.

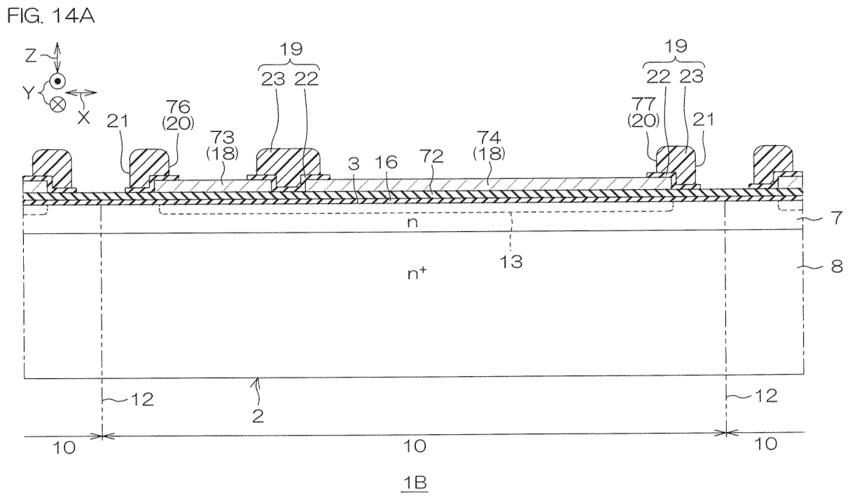

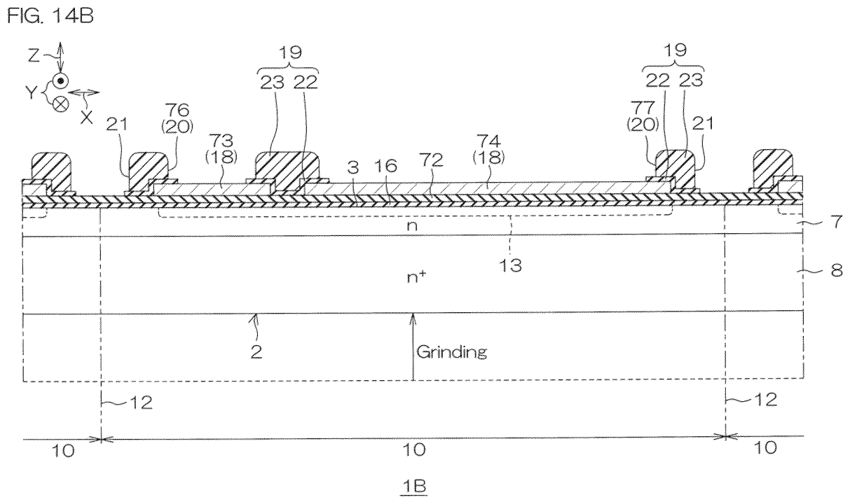

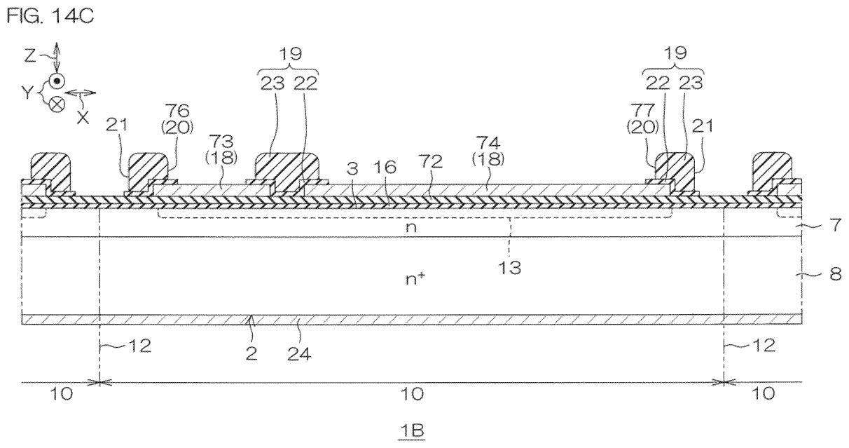

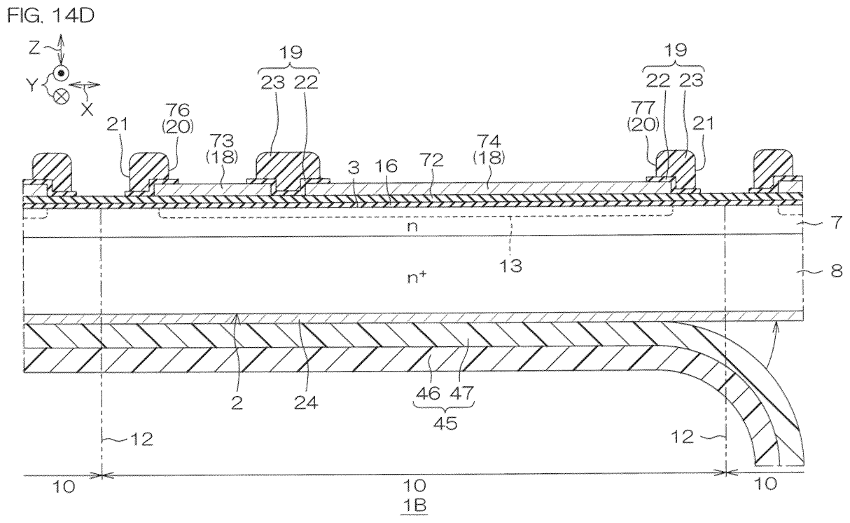

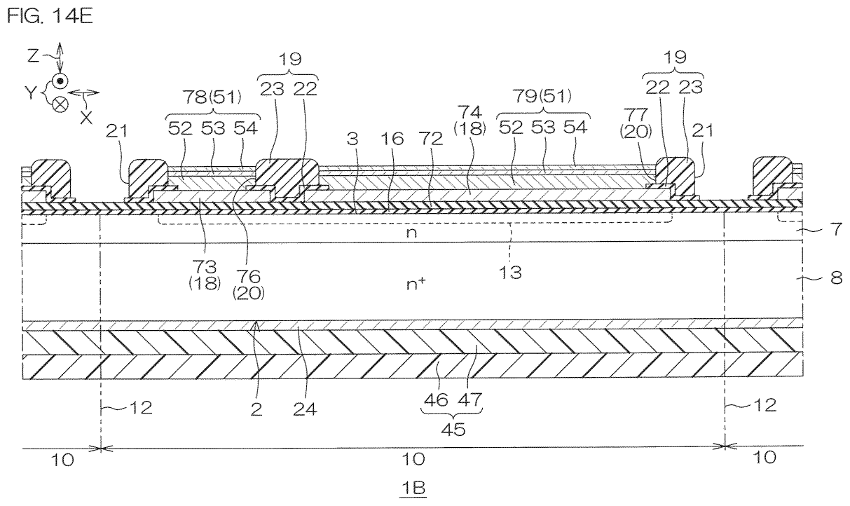

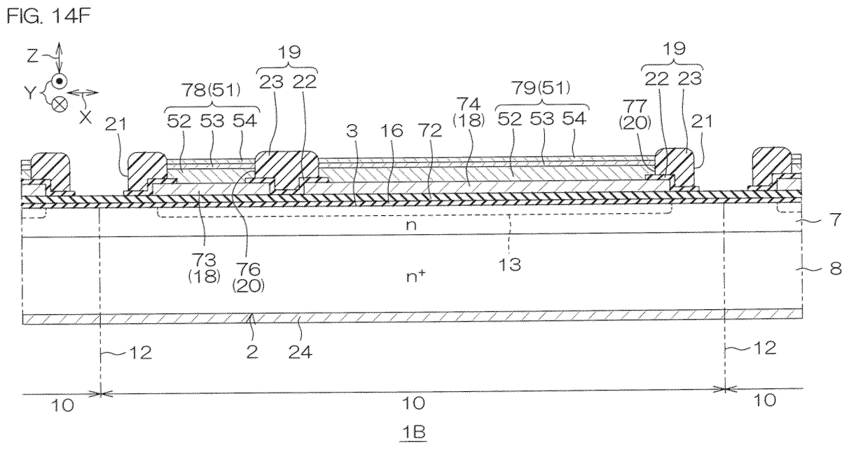

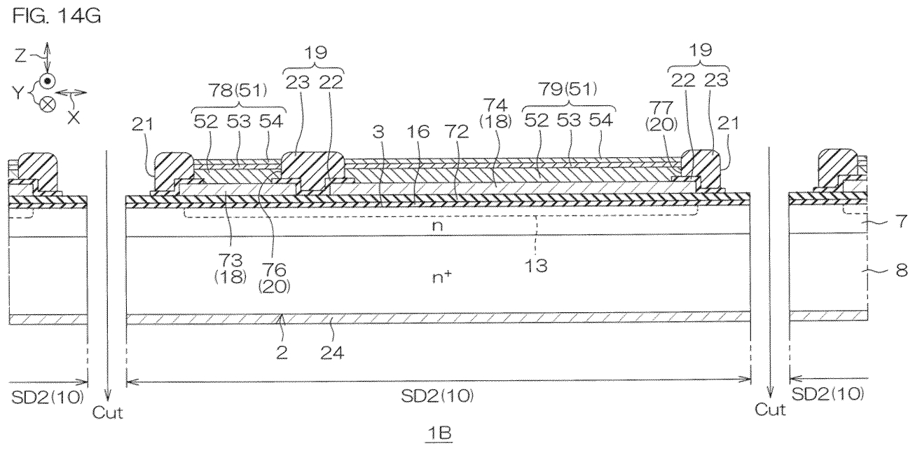

FIG. 14A to FIG. 14G are each a cross-sectional view which shows a manufacturing method for a semiconductor device SD2 according to the wafer structure 1B shown in FIG. 10. FIG. 14A to FIG. 14G are also some of the manufacturing steps of the wafer structure 1B.

With reference to FIG. 14A, a wafer structure 1B before a step of forming the second electrode 24 is prepared. The wafer structure 1B includes the body region 60, the source region 61, the first trench structure 62, the second trench structure 66, the contact region 70, the well region 71, the main surface insulating film 16, the interlayer insulating film 72, the gate electrode 73 (first electrode 18), the source electrode 74 (first electrode 18), the gate wiring electrode 75 and the insulating film 19 in each of the device regions 10. The wafer structure 1B before the step of forming the second electrode 24 includes the wafer 2 having a thickness of not less than 200 μm. The wafer 2 may have a thickness of not less than 200 μm and not more than 1000 μm. The wafer 2 preferably has the thickness of not less than 250 μm and not more than 500 μm.

Next, with reference to FIG. 14B, a step of thinning the wafer 2 is carried out. The wafer 2 may be thinned from the second main surface 4 side by at least one of a grinding method and an etching method. In this embodiment, the wafer 2 is thinned by the grinding method applied to the second main surface 4. In this embodiment, the wafer 2 is ground until the thickness of less than 200 μm is attained. Thereby, a grinding mark is formed in the second main surface 4.

Next, with reference to FIG. 14C, a step of forming the second electrode 24 is carried out. The step of forming the second electrode 24 is carried out through the same steps as those shown in the aforementioned FIG. 9A to FIG. 9C. Thereby, the plating reaction inhibiting portion 25 having a layout corresponding to a layout of the masking jig 50 is formed at a peripheral edge portion of the second main surface 4.

Next, with reference to FIG. 14D, the protective tape 45 is adhered to the second electrode 24 and the plating reaction inhibiting portion 25 (peripheral edge portion of second main surface 4). Thereby, the wafer structure 1B shown in FIG. 10 to FIG. 13 is manufactured. The wafer structure 1B is handled in a state that the protective tape 45 is adhered.

Next, with reference to FIG. 14E, the plating film 51 is formed on the first electrode 18 by a plating method. In this embodiment, the step of forming the plating film 51 includes a step of forming a gate plating film 78 on the gate electrode 73 and a step of forming a source plating film 79. The plating film 51 (gate plating film 78 and source plating film 79) may be regarded as one component of the wafer structure 1B.

As with the first embodiment, the step of forming the plating film 51 includes a step of forming the Ni plating film 52, the Pd plating film 53 and the Au plating film 54 in that order from the first electrode 18 side. The Ni plating film 52, the Pd plating film 53 and the Au plating film 54 are formed inside the pad opening 20 (gate pad opening 76 and source pad opening 77) in the same mode as that of the first embodiment.

As a matter of course, the plating film 51 may have a laminated structure including only the Ni plating film 52 and the Au plating film 54 laminated in that order from the first electrode 18 side. Also, the plating film 51 may have a single layer structure which is made of the Ni plating film 52, the Pd plating film 53 or the Au plating film 54.

Next, with reference to FIG. 14F, the protective tape 45 is peeled from the second main surface 4 and the second electrode 24. This step includes a step of irradiating ultraviolet rays to the adhesive layer 47 of the protective tape 45 and decreasing an adhesive force of the adhesive layer 47. This step also includes a step of peeling the base film 46 from the second electrode 24 together with the adhesive layer 47.

Next, with reference to FIG. 14G, the wafer 2 is cut along the plurality of scheduled-to-be-cut lines 12. The wafer 2 may be cut (sliced) by a dicing blade or may be cut (cleaved) by a cleavage method with the use of a laser light irradiation step. Through the steps including the above, the semiconductor device SD2 (in this embodiment, SiC semiconductor device) is manufactured.

As described so far, the same effects as those described in the wafer structure 1A can be obtained also by the wafer structure 1B. Also, the same effects as those described in the manufacturing method for the semiconductor device SD2 according to the wafer structure 1A can also be obtained by the manufacturing method for the semiconductor device SD2 according to the wafer structure 1B.

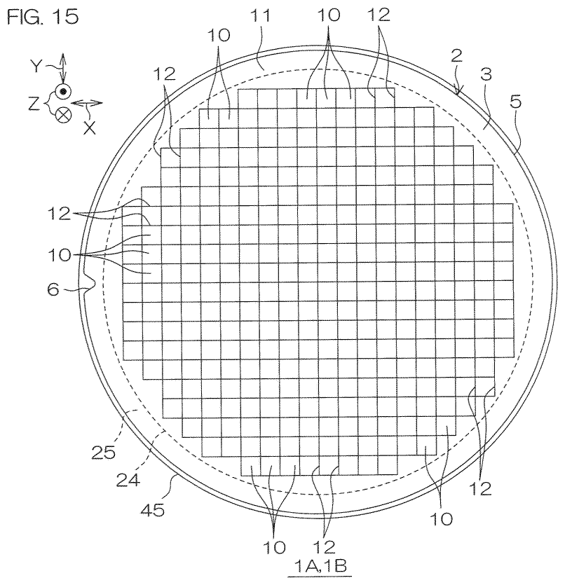

FIG. 15 is a plan view which shows the wafer 2 according to a modified example applied to each of the aforementioned embodiments. The mark 6 of the wafer 2 according to each of the aforementioned embodiments includes an orientation flat. In contrast, with reference to FIG. 15, the mark 6 of the wafer 2 according to the modified example includes an orientation notch which is hollowed in a spindle shape (tapered shape or triangular shape) toward the central portion of the first main surface 3 in the side surface 5.

The orientation notch may be hollowed in the first direction X or the second direction Y (a-axial direction or m-axial direction) in a plan view. As a matter of course, the mark 6 may include a first orientation notch hollowed in the first direction X and a first orientation notch hollowed in the second direction Y. Also, the mark 6 may include at least one orientation flat and at least one orientation notch.

The second electrode 24 is not required to have a portion extending linearly at a portion along the orientation notch. The second electrode 24 covers the second main surface 4 at an interval inwardly from the orientation notch such as to expose the orientation notch. The second electrode 24 may expose the peripheral edge portion of the second main surface 4 in a circular annular shape. That is, the plating reaction inhibiting portion 25 may expose the peripheral edge portion of the second main surface 4 in a circular annular shape in a region along the mark 6 and in a region outside the mark 6.

The edge portion of the protective tape 45 is not required to have a portion extending linearly at a portion along the orientation notch. The edge portion of the protective tape 45 may be formed in a circular shape over an entire periphery of the peripheral edge of the second main surface 4 in a plan view.

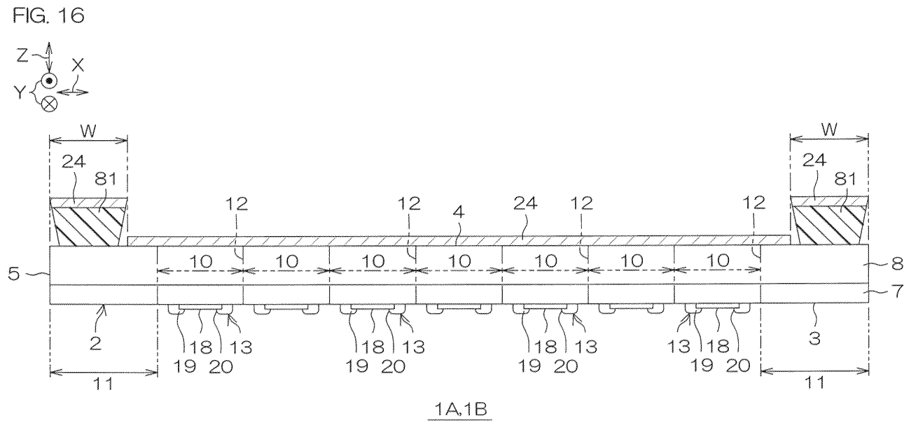

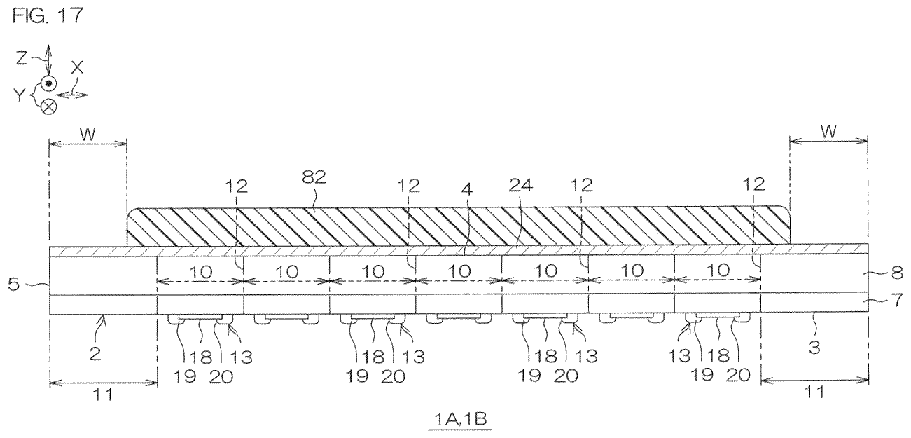

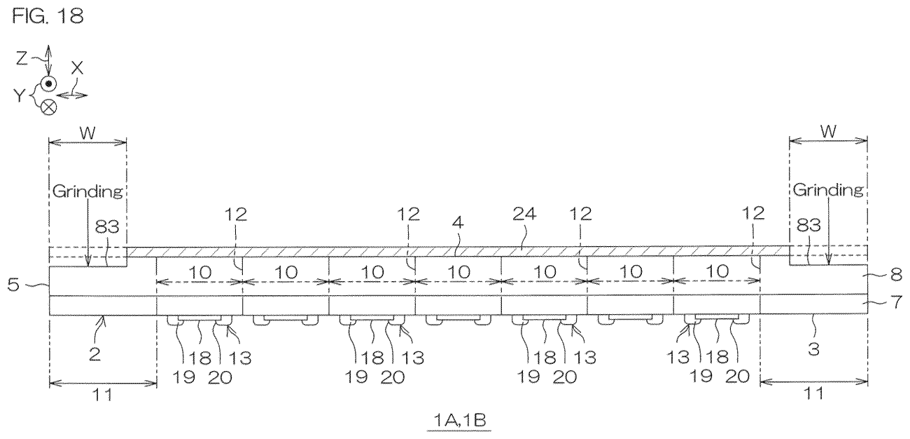

FIG. 16 is a schematic cross-sectional view showing the step of forming the second electrode 24 according to a first modified example which is applied to each of the aforementioned embodiments. FIG. 17 is a schematic cross-sectional view showing the step of forming the second electrode 24 according to a second modified example which is applied to each of the aforementioned embodiments. FIG. 18 is a schematic cross-sectional view showing the step of forming the second electrode 24 according to a third modified example which is applied to each of the aforementioned embodiments. In each of the aforementioned embodiments, the step of forming the second electrode 24 by using the masking jig 50 has been described.

However, with reference to FIG. 16, the second electrode 24 may be formed on the second main surface 4 by a lift-off method. In this case, in place of the masking jig 50, a resist mask 81 is formed on the second main surface 4 and the resist mask 81 may be removed after film formation of the second electrode 24. With man-hours and loads to the wafer 2 taken into account, a step of using the masking jig 50 is preferable.

As a matter of course, with reference to FIG. 17, the second electrode 24 may be formed in a predetermined layout by an etching method. In this case, after film formation of the second electrode 24 on the second main surface 4, a resist mask 82 with a predetermined layout is formed on the second electrode 24, and the second electrode 24 is formed in the predetermined layout by an etching method via the resist mask 82. After removal of unnecessary portions of the second electrode 24, the resist mask 82 is removed. With man-hours and loads to the wafer 2 taken into account, the step of using the masking jig 50 is preferable.

Also, with reference to FIG. 18, the second electrode 24 may be formed in a predetermined layout by a grinding method. In this case, unnecessary portions of the second electrode 24 may be removed by a bevel grinding method which is given to the peripheral edge portion of the second electrode 24 (peripheral edge portion of second main surface 4). In this case, the wafer 2 may be partially removed together with a part of the second electrode 24. That is, the plating reaction inhibiting portion 25 may have a step portion 83 digging down toward the first main surface 3 at the peripheral edge portion of the second main surface 4. With man-hours and loads to the wafer 2 taken into account, the step of using the masking jig 50 is preferable.

Although the embodiments have been described above, each of the embodiments can be carried out in yet other modes. For example, in the step of thinning the wafer 2 according to each of the aforementioned embodiments, the second region 8 may be removed until a thickness less than the thickness of the first region 7 is reached. As a matter of course, in the step of thinning the wafer 2 according to each of the aforementioned embodiments, the second region 8 may be removed entirely. That is, the wafer 2 having a single layer structure made of the first region 7 (SiC epitaxial layer) may be formed.

In the above cases, in the step of adhering the protective tape 45, the protective tape 45 having a thickness larger than that of the wafer 2 may be adhered on the second main surface 4 side. Where a member which reinforces or supports the wafer 2 is provided on the first main surface 3 side, the protective tape 45 having the thickness smaller than that of the wafer 2 may be adhered on the second main surface 4 side.

In each of the aforementioned embodiments, there has been shown an example in which the functional device 13 includes one of an SBD and a MISFET. However, the functional device 13 may include both of the SBD and the MISFET. That is, both of the SBD and the MISFET may be formed inside the same device region 10. As a matter of course, in each of the aforementioned embodiments, the functional device 13 including the SBD and the functional device 13 including the MISFET may be formed in a different device region 10 in the same wafer 2.

In the aforementioned second embodiment, a description has been given of an example in which a trench gate type MISFET is formed as an example of the functional device 13. However, the functional device 13 may include a planar gate-type MISFET in place of the trench gate-type.

In the aforementioned second embodiment, in place of the n-type second region 8, a p-type second region 8 may be adopted. In this case, the functional device 13 includes an IGBT (Insulated Gate Bipolar Transistor) in place of the MISFET. In this case, a specific configuration is obtained by replacing a “source” of the MISFET with an “emitter” of the IGBT and by replacing a “drain” of the MISFET with a “collector” of the IGBT in the previous description.

In each of the aforementioned embodiments, there has been explained a configuration in which the first conductivity type is an n-type and the second conductivity type is a p-type. However, in each of the aforementioned embodiments, there may be adopted a configuration in which the first conductivity e is a p-type and the second conductivity type is an n-type. In this case, a specific configuration can be obtained by replacing the n-type region with the p-type region and replacing the p-type region with the n-type region in the foregoing description and the accompanying drawings.

Hereinafter, features extracted from this Description and the drawings are shown. Hereinafter, alphanumeric characters in the parentheses represent corresponding components, etc., in each of the aforementioned embodiments, and yet this representation does not denote that the scope of each clause is limited to the embodiments. The “wafer structure” according to the following clauses may be replaced by a “wide band gap semiconductor wafer structure,” an “SiC wafer structure,” etc., as necessary. Also, the “semiconductor device” according to the following clauses may be replaced by a “wide band gap semiconductor device,” an “SiC semiconductor device,” etc., as necessary.

[A1] A wafer structure (1A, 1B) comprising: a wafer (2) which has a first surface (3) on one side and a second surface (4) on the other side; a first electrode (18) which covers the first surface (3); a second electrode (24) which covers an inward portion of the second surface (4) such as to expose a peripheral edge portion of the second surface (4); and a protective tape (45) which has characteristics that an adhesion to the peripheral edge portion of the second surface (4) is higher than an adhesion to the second electrode (24) and which is adhered to the peripheral edge portion of the second surface (4) and the second electrode (24).

[A2] The wafer structure (1A, 1B) according to A1, wherein the second electrode (24) has a plating reaction speed higher than a plating reaction speed of the wafer (2) and exposes the peripheral edge portion of the wafer (2) as a plating reaction inhibiting portion (25), and the protective tape (45) is adhered to the plating reaction inhibiting portion (25).

[A3] The wafer structure (1A, 1B) according to A1 or A2, wherein the wafer (2) includes an SiC monocrystal, the second electrode (24) exposes the SiC monocrystal from the peripheral edge portion of the second surface (4), and the protective tape (45) is adhered to the SiC monocrystal at the peripheral edge portion of the second surface (4).

[A4] The wafer structure (1A, 1B) according to any one of A1 to A3, wherein the wafer (2) has a thickness of less than 200 μm.

[A5] The wafer structure (1A, 1B) according to any one of A1 to A4, wherein the second electrode (24) exposes an entire periphery of the peripheral edge portion, and the protective tape (45) is adhered to the entire periphery of the peripheral edge portion.

[A6] The wafer structure (1A, 1B) according to any one of A1 to A5, wherein an exposure width (W) of the peripheral edge portion is larger than a thickness of the second electrode (24).

[A7] The wafer structure (1A, 1B) according to A6, wherein the exposure width (W) is larger than a thickness of the wafer (2).

[A8] The wafer structure (1A, 1B) according to any one of A1 to A7, wherein the wafer (2) has the second surface (4) which has a grinding mark, the second electrode (24) exposes the peripheral edge portion having the grinding mark, and the protective tape (45) is adhered to the peripheral edge portion having the grinding mark.

[A9] The wafer structure (1A, 1B) according to any one of A1 to A8, wherein the second surface (4) is made of a flat surface.

[A10] The wafer structure (1A, 1B) according to any one of A1 to A9, further comprising: a plating film (51) which covers the first electrode (18).

[A11] The wafer structure (1A, 1B) according to A10, wherein the plating film (51) includes at least one among an Ni plating film (52), a Pd plating film (53) and an Au plating film (54).

[A12] The wafer structure (1A, 1B) according to any one of A1 to A11, further comprising: device regions (10) which are set in an inward portion of the first surface (3); and wherein the second electrode (24) exposes a region outside the device regions (10) in a plan view.

[A13] A manufacturing method for a semiconductor device (SD1, SD2) comprising: a step of preparing a wafer structure (1A, 1B) including a wafer (2) which has a first surface (3) on one side and a second surface (4) on the other side, and a first electrode (18) which covers the first surface (3); a step of forming a second electrode (24) which covers an inward portion of the second surface (4) such as to expose a peripheral edge portion of the second surface (4); and a step of adhering a protective tape (45), which has characteristics that an adhesion to the peripheral edge portion of the second surface (4) is higher than an adhesion to the second electrode (24), to the peripheral edge portion of the second surface (4) and to the second electrode (24).

[A14] The manufacturing method for the semiconductor device (SD1, SD2) according to A13, wherein the second electrode (24) has a plating reaction speed higher than a plating reaction speed of the wafer (2) and exposes the peripheral edge portion of the wafer (2) as a plating reaction inhibiting portion (25).

[A15] The manufacturing method for the semiconductor device (SD1, SD2) according to A13 or A14, further comprising: a step of immersing the wafer structure (1A, 1B) in a plating solution in a state that the protective tape (45) is adhered and forming a plating film (51) on the first electrode (18).

[A16] The manufacturing method for the semiconductor device (SD1, SD2) according to A15, wherein the step of forming the plating film (51) includes a step of rocking the wafer structure (1A, 1B) in the plating solution.

[A17] The manufacturing method for the semiconductor device (SD1, SD2) according to A15 or A16, wherein the step of forming the plating film (51) includes at least one step among a step of immersing the wafer structure (1A, 1B) in an Ni plating solution and forming an Ni plating film (52), a step of immersing the wafer structure (1A, 1B) in a Pd plating solution and forming a Pd plating film (53), and a step of immersing the wafer structure (1A, 1B) in an Au plating solution and forming an Au plating film (54).

[A18] The manufacturing method for the semiconductor device (SD1, SD2) according to any one of A13 to A17, wherein the wafer (2) includes an SiC monocrystal, the second electrode (24) exposes the SiC monocrystal from the peripheral edge portion of the second surface (4), and the protective tape (45) is adhered to the SiC monocrystal at the peripheral edge portion of the second surface (4).

[A19] The manufacturing method for the semiconductor device (SD1, SD2) according to any one of A13 to A18, further comprising: a step of preparing the wafer structure (1A, 1B) which includes the wafer (2) having a thickness of not less than 200 μm, and a step of thinning the wafer (2) until the wafer (2) reaches a thickness of less than 200 μm prior to the step of forming the second electrode (24).

[A20] The manufacturing method for the semiconductor device (SD1, SD2) according to A19, wherein the step of thinning the wafer (2) includes a step of grinding the second surface (4) by a grinding method.

While embodiments of the present invention have been described in detail above, those are merely specific examples used to clarify the technical contents. The various technical ideas extracted from this Description are not limited by the order of description, the order of the embodiments, etc., in the Description and can be combined as appropriate with each other.

What is claimed is:

1. A wafer structure comprising:
a wafer which has a first surface on one side and a second surface on the other side;
a first electrode which covers the first surface;
a second electrode which covers an inward portion of the second surface such as to expose a peripheral edge portion of the second surface; and
a protective tape which has characteristics that an adhesion to the peripheral edge portion of the second surface is higher than an adhesion to the second electrode and which is adhered to the peripheral edge portion of the second surface and the second electrode.

2. The wafer structure according to claim 1,
wherein the second electrode has a plating reaction speed higher than a plating reaction speed of the wafer and exposes the peripheral edge portion of the wafer as a plating reaction inhibiting portion, and
the protective tape is adhered to the plating reaction inhibiting portion.

3. The wafer structure according to claim 1,
wherein the wafer includes an SiC monocrystal,
the second electrode exposes the SiC monocrystal from the peripheral edge portion of the second surface, and
the protective tape is adhered to the SiC monocrystal at the peripheral edge portion of the second surface.

4. The wafer structure according to claim 1,
wherein the wafer has a thickness of less than 200 μm.

5. The wafer structure according to claim 1,
wherein the second electrode exposes an entire periphery of the peripheral edge portion, and
the protective tape is adhered to the entire periphery of the peripheral edge portion.

6. The wafer structure according to claim 1,
wherein an exposure width of the peripheral edge portion is larger than a thickness of the second electrode.

7. The wafer structure according to claim 6,
wherein the exposure width is larger than a thickness of the wafer.

8. The wafer structure according to claim 1,
wherein the wafer has the second surface which has a grinding mark,
the second electrode exposes the peripheral edge portion having the grinding mark, and
the protective tape is adhered to the peripheral edge portion having the grinding mark.

9. The wafer structure according to claim 1,
wherein the second surface is made of a flat surface.

10. The wafer structure according to claim 1, further comprising:
a plating film which covers the first electrode.

11. The wafer structure according to claim 10,
wherein the plating film includes at least one among an Ni plating film, a Pd plating film and an Au plating film.

12. The wafer structure according to claim 1, further comprising:
device regions which are set in an inward portion of the first surface; and
wherein the second electrode exposes a region outside the device regions in a plan view.

13. A manufacturing method for a semiconductor device comprising:
a step of preparing a wafer structure including a wafer which has a first surface on one side and a second surface on the other side, and a first electrode which covers the first surface;
a step of forming a second electrode which covers an inward portion of the second surface such as to expose a peripheral edge portion of the second surface; and
a step of adhering a protective tape, which has characteristics that an adhesion to the peripheral edge portion of the second surface is higher than an adhesion to the second electrode, to the peripheral edge portion of the second surface and to the second electrode.

14. The manufacturing method for the semiconductor device according to claim 13,
wherein the second electrode has a plating reaction speed higher than a plating reaction speed of the wafer and exposes the peripheral edge portion of the wafer as a plating reaction inhibiting portion.

15. The manufacturing method for the semiconductor device according to claim 13, further comprising:
a step of immersing the wafer structure in a plating solution in a state that the protective tape is adhered, and forming a plating film on the first electrode.

16. The manufacturing method for the semiconductor device according to claim 15,
wherein the step of forming the plating film includes a step of rocking the wafer structure in the plating solution.

17. The manufacturing method for the semiconductor device according to claim 15,
wherein the step of forming the plating film includes at least one step among a step of immersing the wafer structure in an Ni plating solution and forming an Ni plating film, a step of immersing the wafer structure in a Pd plating solution and forming a Pd plating film, and a step of immersing the wafer structure in an Au plating solution and forming an Au plating film.

18. The manufacturing method for the semiconductor device according to claim 13,
wherein the wafer includes an SiC monocrystal,
the second electrode exposes the SiC monocrystal from the peripheral edge portion of the second surface, and
the protective tape is adhered to the SiC monocrystal at the peripheral edge portion of the second surface.

19. The manufacturing method for the semiconductor device according to claim 13, further comprising:
a step of preparing the wafer structure which includes the wafer having a thickness of not less than 200 μm, and
a step of thinning the wafer until the wafer reaches a thickness of less than 200 μm prior to the step of forming the second electrode.

20. The manufacturing method for the semiconductor device according to claim 19,
wherein the step of thinning the wafer includes a step of grinding the second surface by a grinding method.
